(19) United States
(12) Patent Application Publication
(10) Pub. No.: US 2016/0336509 A1
(43) Pub. Date: Nov. 17, 2016

(54) METHODS OF FORMING PATTERNS, METHODS OF MANUFACTURING A MAGNETIC MEMORY DEVICE USING THE METHODS OF FORMING PATTERNS, AND MAGNETIC MEMORY DEVICES MANUFACTURED USING THE SAME

(71) Applicants: Daeeun JEONG, Yongin-si (KR); Yoonjong SONG, Hwaseong-si (KR); Hyunchul SHIN, Seoul (KR)

(72) Inventors: Daeeun JEONG, Yongin-si (KR); Yoonjong SONG, Hwaseong-si (KR); Hyunchul SHIN, Seoul (KR)

(21) Appl. No.: 15/093,994

(22) Filed: Apr. 8, 2016

(30) Foreign Application Priority Data
May 15, 2015 (KR) 10-2015-0067948

(51) Int. Cl. H01L 43/12

(52) U.S. Cl. CPC H01L 43/12

(57) ABSTRACT

A method of forming patterns includes forming an etch target layer on a substrate, patterning the etch target layer to form patterns, forming an insulating layer on sidewalls of the patterns using a first ion beam generated from a first ion source, and removing the insulating layer using a second ion beam generated from a second ion source, wherein each of the first and second ion sources includes an insulating source, and wherein the insulating source includes at least one of oxygen or nitrogen.

### CROSS-REFERENCE TO RELATED APPLICATION

Korean Patent Application No. 10-2015-0067948, filed on May 15, 2015, in the Korean Intellectual Property Office, and entitled: “Methods of Forming Patterns, Methods of Manufacturing A Magnetic Memory Device Using the Methods of Forming Patterns, and Magnetic Memory Devices Manufactured Using the Same,” is incorporated by reference herein in its entirety.

### BACKGROUND

1. Field

Embodiments relate to methods of forming patterns using an ion beam. Embodiments also relate to methods of manufacturing a magnetic memory device using the methods of forming patterns, and magnetic memory devices manufactured using the same.

2. Description of the Related Art

As high-speed and/or low-power consumption electronic devices have been demanded in an electronic industry, high-speed and/or low-voltage semiconductor memory devices included in the electronic devices have been increasingly demanded. To satisfy these demands, a magnetic memory device has been developed as a semiconductor memory device. The magnetic memory device is spotlighted as a next-generation semiconductor memory device because of its high-speed performance and non-volatile characteristics.

Generally, magnetic memory devices may include a magnetic tunnel junction (MTJ) pattern. The MTJ pattern may include two magnetic bodies and an insulating layer disposed between the two magnetic bodies. A resistance value of the MTJ pattern may be varied according to magnetization directions of the two magnetic bodies. For example, if the magnetization directions of the two magnetic bodies are anti-parallel to each other, the MTJ pattern may have a high resistance value. If the magnetization directions of the two magnetic bodies are parallel to each other, the MTJ pattern may have a low resistance value. Data may be represented in the MTJ pattern by means of a difference between the resistance values.

The electronic industry is increasingly demanding more highly integrated and lower power consuming magnetic memory devices. Accordingly, research is being conducted into various ways to satisfy these demands.

### SUMMARY

Embodiments may provide methods of forming patterns with easily removed residues.

Embodiments may also provide magnetic memory devices capable of improving reliability and methods of manufacturing the same.

In one aspect, a method of forming patterns may include forming an etch target layer on a substrate, patterning the etch target layer to form patterns, forming an insulating layer on sidewalls of the patterns using a first ion beam generated from a first ion source, and removing the insulating layer using a second ion beam generated from a second ion source. Each of the first and second ion sources may include an insulating source, and the insulating source may include at least one of oxygen or nitrogen.

In an embodiment, a concentration of the insulating source in the first ion source may be different from a concentration of the insulating source in the second ion source.

In an embodiment, the concentration of the insulating source in the first ion source may be higher than the concentration of the insulating source in the second ion source.

In an embodiment, the concentration of the insulating source in the first ion source may range from about 30 at % to about 50 at %.

In an embodiment, the concentration of the insulating source in the second ion source may range from about 0 at % to about 10 at %.

In an embodiment, each of the first ion source and the second ion source may further include a non-volatile element.

In an embodiment, forming the insulating layer may include irradiating the first ion beam at a first angle with respect to a top surface of the substrate. Removing the insulating layer may include irradiating the second ion beam at a second angle with respect to the top surface of the substrate. The first angle may be different from the second angle.

In an embodiment, the first angle may be greater than the second angle.

In an embodiment, the first angle may range from about 80 degrees to about 90 degrees.

In an embodiment, the second angle may range from about 0 degree to about 45 degrees.

In an embodiment, forming the insulating layer may include forming a first insulating layer and a second insulating layer which are sequentially stacked on the sidewalls of the patterns. The first insulating layer may be disposed between the second insulating layer and the sidewalls of the patterns. The insulating source of the first ion source may be oxygen when the first insulating layer is formed, and the insulating source of the first ion source may include oxygen and nitrogen when the second insulating layer is formed.

In an embodiment, a nitrogen concentration of the second insulating layer may be higher than a nitrogen concentration of the first insulating layer.

In an embodiment, forming the insulating layer may include irradiating the first ion beam at a first angle with respect to a top surface of the substrate to form a first insulating layer, irradiating the first ion beam at a second angle with respect to the top surface of the substrate to form a second insulating layer, and irradiating the first ion beam at a third angle with respect to the top surface of the substrate to form a third insulating layer. The second angle may be smaller than the first angle and the third angle.

In an embodiment, a concentration of the insulating source in the first ion source may be higher than a concentration of the insulating source in the second ion source.

In an embodiment, the first ion beam may have a first incident energy when the first insulating layer is formed, and the first ion beam may have a second incident energy greater than the first incident energy when the third insulating layer is formed.

In an embodiment, removing the insulating layer may include irradiating the second ion beam at a fourth angle with respect to the top surface of the substrate. The fourth angle may be smaller than the first angle and the third angle.

In an embodiment, each of the first angle and the third angle may range from about 80 degrees to about 90 degrees, and each of the second angle and the fourth angle may range from about 0 degree to about 45 degrees.

In an embodiment, forming the insulating layer may include forming a first insulating layer and a second insulating layer which are sequentially stacked on the sidewalls of the patterns. The first insulating layer may be disposed between the second insulating layer and the sidewalls of the patterns. The first ion beam may have a first incident energy when the first insulating layer is formed, and the first ion beam may have a second incident energy greater than the first incident energy when the second insulating layer is formed.

In an embodiment, a concentration of the insulating source in the first ion source may be higher than a concentration of the insulating source in the second ion source.

In an embodiment, the first ion beam may be irradiated at a first angle with respect to a top surface of the substrate when the first insulating layer is formed, and the first ion beam may be irradiated at a second angle with respect to the top surface of the substrate when the second insulating layer is formed. Removing the insulating layer may include irradiating the second ion beam at a third angle with respect to the top surface of the substrate, and the third angle may be smaller than the first angle and the second angle.

In an embodiment, the etch target layer may include a conductive material.

In another aspect, a method of manufacturing a magnetic memory device may include forming a magnetic tunnel junction layer on a substrate, patterning the magnetic tunnel junction layer to form magnetic tunnel junction patterns, forming an insulating layer on sidewalls of the magnetic tunnel junction patterns using a first ion beam generated from a first ion source, and removing the insulating layer using a second ion beam generated from a second ion source. Each of the first and second ion sources may include an insulating source, and the insulating source may include at least one of oxygen or nitrogen.

In an embodiment, a concentration of the insulating source in the first ion source may be higher than a concentration of the insulating source in the second ion source.

In an embodiment, each of the first and second ion sources may further include a non-volatile element.

In an embodiment, forming the insulating layer may include irradiating the first ion beam at a first angle with respect to a top surface of the substrate. Removing the insulating layer may include irradiating the second ion beam at a second angle with respect to the top surface of the substrate. The first angle may be greater than the second angle.

In an embodiment, the method may further include forming top electrodes on the magnetic tunnel junction patterns before forming the insulating layer. Each of the top electrodes may be spaced apart from the substrate with each of the magnetic tunnel junction patterns interposed therebetween, and at least a portion of each of the top electrodes may be oxidized or nitrified during the formation of the insulating layer.

In an embodiment, each of the magnetic tunnel junction patterns may include a free layer, a reference layer, and a tunnel barrier disposed between the free layer and the reference layer, and each of the free layer and the reference layer may have a magnetization direction substantially perpendicular to a top surface of the substrate.

In an embodiment, each of the magnetic tunnel junction patterns may include a free layer, a reference layer, and a tunnel barrier disposed between the free layer and the reference layer, and each of the free layer and the reference layer may have a magnetization direction substantially parallel to a top surface of the substrate.

In yet another aspect, a method of forming patterns may include forming an etch target layer on a substrate, patterning the etch target layer to form patterns, irradiating a first ion beam from a first ion source toward the patterns, such that a first insulating source in the first ion source interacts with residue on the patterns to form an insulating layer on sidewalls of the patterns, and removing the insulating layer from the sidewalls of the patterns, wherein the first insulating source includes at least one of oxygen or nitrogen.

In an embodiment, removing the insulating layer from the sidewalls of the patterns may be performed using a second ion beam generated from a second ion source, the second ion source including a second insulating source, and the second insulating source including at least one of oxygen or nitrogen.

In an embodiment, a concentration of the first insulating source in the first ion source may be higher than a concentration of the second insulating source in the second ion source.

In an embodiment, irradiating the first ion beam from the first ion source may include interacting the first insulating source in the first ion beam with metal elements in the residue on sidewalls of the patterns to form the insulating layer, the residue including metal elements of the tech target layer redeposited on the sidewalls of the patterns after patterning the etch target layer.

In an embodiment, removing the insulating layer from the sidewalls of the patterns may include removing the residue from the sidewalls of the patterns.

In still another aspect, a magnetic memory device may include a top electrode on a substrate, a magnetic tunnel junction pattern between the substrate and the top electrode, and an insulating layer on a sidewall of the top electrode. The insulating layer may include at least one of oxygen or nitrogen.

In an embodiment, the insulating layer may further include the same metal element as the top electrode.

### BRIEF DESCRIPTION OF THE DRAWINGS

Features will become apparent to those of ordinary skill in the art by describing in detail exemplary embodiments with reference to the attached drawings, in which:

FIG. 1 illustrates a flow chart of a method of forming a pattern according to embodiments.

FIGS. 2 to 5 illustrate cross-sectional views of stages in the method of FIG. 1.

FIG. 6 illustrates an enlarged view of portion ‘A’ of FIG. 4 to explain a penetration depth of an insulating source at a surface portion of a pattern according to an irradiation angle of a first ion beam.

FIG. 7 illustrates a graph of an etch rate of an etch target material according to an irradiation angle of a second ion beam and an ion source of the second ion beam.

FIG. 8 illustrates a detailed flow chart of operation S300 of FIG. 1.

FIGS. 9 and 10 illustrate cross-sectional views of stages of operation S300 of FIG. 1.

FIG. 11 illustrates a detailed flow chart of operation S300 of FIG. 1.

FIGS. 12 to 14 illustrate cross-sectional views of stages of operation S300 of FIG. 1.

FIG. 15 illustrates a detailed flow chart of operation S300 of FIG. 1.

FIGS. 16 and 17 illustrate cross-sectional views of stages in operation S300 of FIG. 1.

FIG. 18 illustrates a detailed flow chart of operation S300 of FIG. 1.

FIGS. 19 to 21 illustrate cross-sectional views of stages in operation S300 of FIG. 1.

FIG. 22 illustrates a flow chart of a method of manufacturing a magnetic memory device according to an embodiment.

FIGS. 23 to 27 illustrate cross-sectional views of stages in a method of manufacturing a magnetic memory device according to an embodiment.

FIG. 28A illustrates a cross-sectional view of a magnetic tunnel junction (MTJ) pattern according to an embodiment.

FIG. 28B illustrates a cross-sectional view of a MTJ pattern according to an embodiment.

FIG. 29 illustrates a schematic block diagram of an electronic system including a semiconductor device according to an embodiment.

FIG. 30 illustrates a schematic block diagram of a memory card including a semiconductor device according to an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art. As used herein, the term “and/or” includes any and all combinations of one or more of the associated listed items.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

The embodiments in the detailed description will be described with cross-sectional, perspective and plan views as ideal exemplary views. Accordingly, shapes of the exemplary views may be modified according to manufacturing techniques and/or allowable errors. Therefore, the embodiments are not limited to the specific shape illustrated in the exemplary views, but may include other shapes that may be created according to manufacturing processes. Areas exemplified in the drawings have general properties, and are used to illustrate specific shapes of elements. Thus, this should not be construed as limiting.

It will be also understood that although the terms first, second, third etc. may be used herein to describe various elements, these elements should not be limited by these terms. These terms are only used to distinguish one element from another element. Exemplary embodiments explained and illustrated herein include their complementary counterparts.

The terminology used herein is for the purpose of describing particular embodiments only and is not intended to limit. As used herein, the singular terms “a,” “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Hereinafter, embodiments will be fully described with reference to the accompanying drawings.

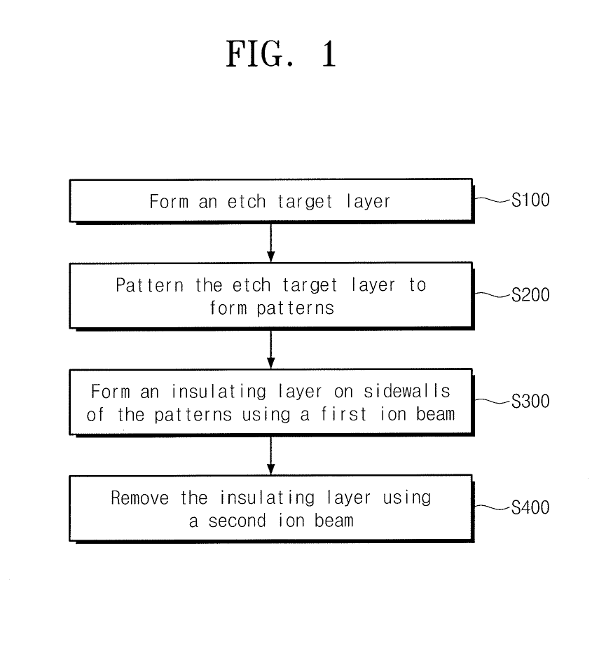

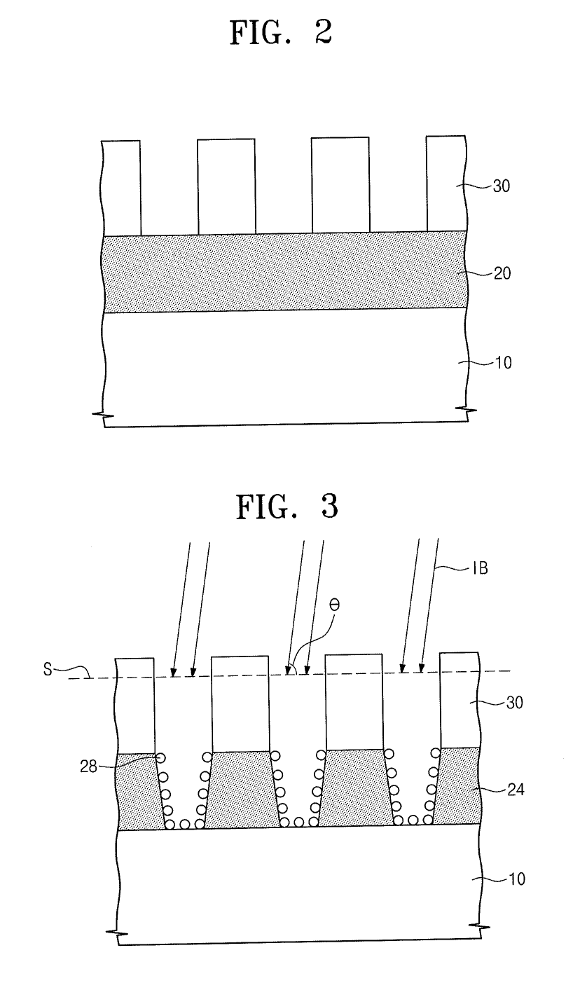

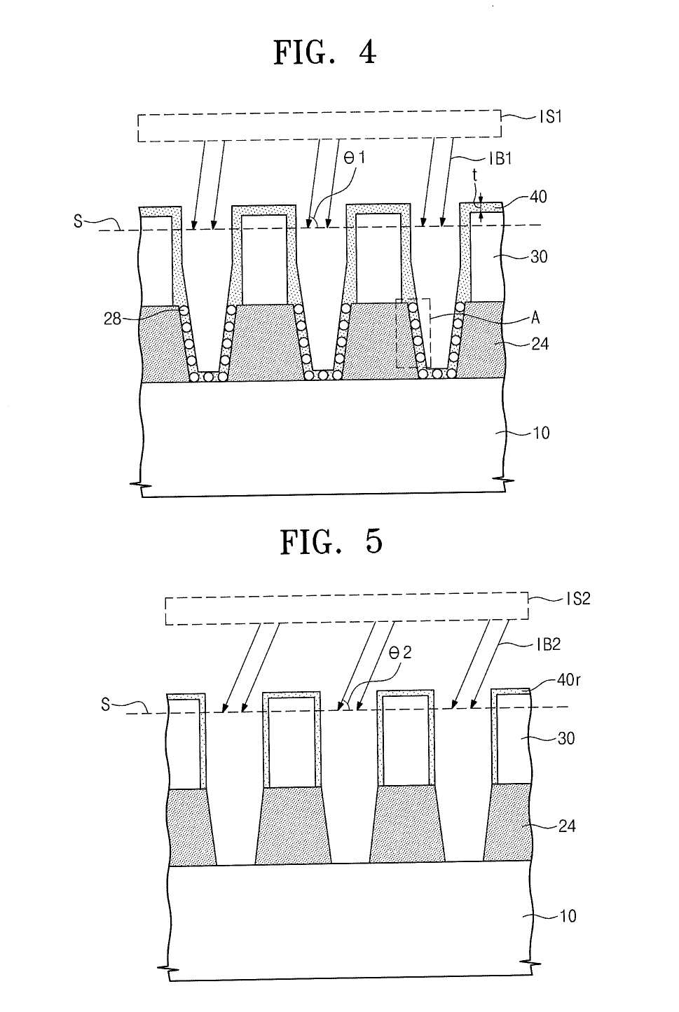

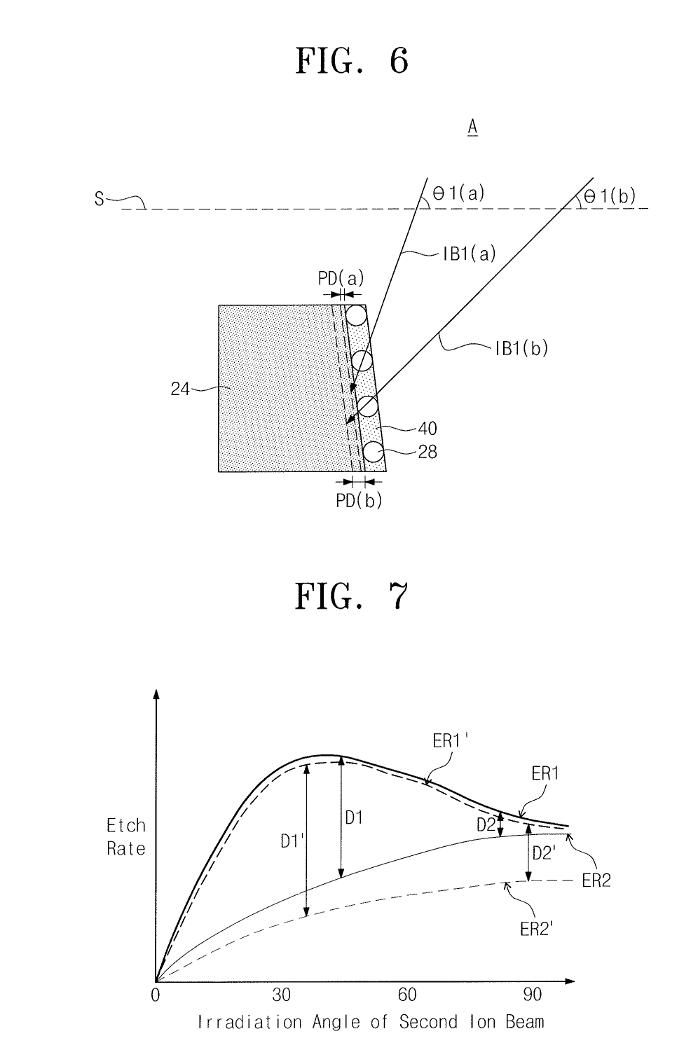

FIG. 1 is a flow chart illustrating a method of forming a pattern according to embodiments, and FIGS. 2 to 5 are cross-sectional views illustrating stages in the method of forming a pattern of FIG. 1. FIG. 6 is an enlarged view of a portion ‘A’ of FIG. 4 to explain a penetration depth of an insulating source at a surface portion of a pattern according to an irradiation angle of a first ion beam, and FIG. 7 is a graph illustrating an etch rate of an etch target material according to an irradiation angle of a second ion beam and an ion source of the second ion beam.

Referring to FIGS. 1 and 2, an etch target layer 20 may be formed on a substrate 10 (S100). The substrate 10 may include a selection component, e.g., a transistor or a diode. The etch target layer 20 may include a conductive material. In an embodiment, the etch target layer 20 may include a metal element. Mask patterns 30 may be formed on the etch target layer 20.

Referring to FIGS. 1 and 3, the etch target layer 20 may be etched using the mask patterns 30 as etch masks to form patterns 24 spaced apart from each other on the substrate 10 (S200). The etching process of the target layer 20 may be performed using a sputtering method.

In detail, referring to FIG. 3, ion beams IB may be provided toward the substrate 10 having the mask patterns 30 thereon. The ion beams IB may include, e.g., argon ions (Ar⁺). The ion beams IB may be irradiated to a surface of the etch target layer 20 at a predetermined angle θ with respect to a reference line S parallel to a top surface of the substrate 10. The etch target layer 20 may be etched by the ion beams IB so as to be divided into the patterns 24. The substrate 10 may rotate with a rotation axis perpendicular to the top surface of the substrate 10 during the etching process, and thus, the etch target layer 20 between the mask patterns 30 may be symmetrically etched.

Etch residues 28 generated from the mask patterns 30 and the etch target layer 20 during the etching process may be re-deposited on sidewalls of the patterns 24 and on portions of the substrate 10 exposed between the patterns 24. The etch residue 28 may include a conductive material. For example, the etch residue 28 may include a metal element.

Referring to FIGS. 1, 4, and 6, an insulating layer 40 may be formed on the sidewalls of the patterns 24 by first ion beams IB1 (S300). The insulating layer 40 may extend, e.g., conformally, on surfaces of the mask patterns 30, sidewall surfaces of the patterns 24, and portions of the substrate 10 exposed between the patterns 24. Forming the insulating layer 40 may include oxidizing or nitrifying the etch residues 28. A portion of each of the mask patterns 30 may be oxidized or nitrified during the oxidation or nitrification of the etch residues 28.

The insulating layer 40 may be formed using a sputtering method. In detail, the first ion beams IB1 may be provided, e.g., irradiated, toward the substrate 10 having the patterns 24 thereon. The first ion beams IB1 may be generated from a first ion source IS1. The first ion source IS1 may include an insulating source, e.g., the first ion source IS1 may include a source of an insulating component. The insulating source may include at least one of oxygen or nitrogen. The etch residues 28 may be oxidized or nitrified by the first ion beams IB1 including the insulating source, and a portion of each of the mask patterns 30 may also be oxidized or nitrified by the first ion beams IB1 including the insulating source. The first ion source IS1 may further include a non-volatile element (e.g., argon). For example, a concentration of the insulating source in the first ion source IS1 may range from about 30 at % to about 50 at %, e.g., the first ion source IS1 may include about 30 at % to about 50 at % of oxygen or nitrogen and a remainder of argon.

The first ion beams IB1 may be irradiated from the first ion source IS1 toward the surfaces of the substrate 10, the patterns 24, and the mask patterns 30 at a first angle θ1 with respect to the reference line S. For example, the first ion beams IB1 may penetrate the patterns 24 and the mask patterns 30 to a predetermined depth, such that the insulating source, e.g., oxygen or nitrogen, in the first ion beams IB1 interacts with portions of the patterns 24, i.e., and the etch residues 28 on sidewalls thereof, and the mask patterns 30 to form the insulating layer 40 conformally on the patterns 24 and the mask patterns 30. For example, the insulating source in the first ion beams IB1 may interact with substantially the entirety of the etch residues 28 on the patterns 24, so the resultant insulating layer 40 may include, e.g., encompass, substantially the entirety of the etch residues 28 on the patterns 24.

As illustrated in FIG. 6, a penetration depth of the insulating source from the surface of the pattern 24 into the inside of the pattern 24 may increase as the first angle θ1 decreases (i.e., ♭1(a)→θ1(b)). In other words, a penetration depth PD(a) of the insulating source of a first ion beam IB1(a) irradiated at the first angle θ1 which is a relatively high angle (i.e., θ1=θ1(a)) may be smaller than a penetration depth PD(b) of the insulating source of a first ion beam IB1(b) irradiated at the first angle θ1 which is a relative low angle (i.e., θ1=θ1(b)). The insulating layer 40 may be formed to have a more uniform thickness t as the penetration depth of the insulating source decreases (i.e., PD(b)→PD(a)). Thus, the first ion beams IB1 may be irradiated at a relatively high angle with respect to the reference line S during the process of forming the insulating layer 40, e.g., at angle θ1=θ1(a) of FIG. 6. In an embodiment, the first angle θ1 may range from about 80 degrees to about 90 degrees with respect to the reference line S.

Referring to FIGS. 1, 5, and 7, the insulating layer 40 may be removed using second ion beams IB2 (S400). Since the insulating layer 40 is removed, the sidewalls of the patterns 24 and the substrate 10 between the patterns 24 may be exposed. According to an embodiment, residual portions 40r of the insulating layer 40 may not be removed from the surface of the mask patterns 30.

The insulating layer 40 may be removed using a sputtering method. In detail, the second ion beams IB2 may be provided, e.g., irradiated, toward the substrate 10 having the insulating layer 40 thereon. The second ion beams IB2 may be generated from a second ion source IS2. The second ion source IS2 may include an insulating source, e.g., at least one of oxygen or nitrogen. The second ion source IS2 may further include a non-volatile element (e.g., argon). A concentration of the insulating source in the second ion source IS2 may be different from the concentration of the insulating source in the first ion source IS1. In an embodiment, the concentration of the insulating source in the second ion source IS2 may be lower than the concentration of the insulating source in the first ion source IS1. For example, the concentration of the insulating source in the second ion source IS2 may range from about 0 at % to about 10 at %, e.g., the second ion source IS2 may include about 0 at % to about 10 at % of oxygen or nitrogen and a remainder of argon.

The second ion beams IB2 may be irradiated to a surface of the insulating layer 40 at a second angle θ2 with respect to the reference line S. The second angle θ2 may be different from the first angle θ1. In an embodiment, the second angle θ2 may be smaller than the first angle θ1.

According to an embodiment, the patterns 24 may include a metal, and the insulating layer 40 may include a metal oxide and/or a metal nitride. In this case, as illustrated in FIG. 7, if the second ion beam IB2 includes only a non-volatile element (e.g., argon ions), an etch rate ER1 of the insulating layer 40 by the second ion beam IB2 may be different from an etch rate ER2 of the pattern 24 by the second ion beam IB2. A difference between the etch rate ER1 of the insulating layer 40 and the etch rate ER2 of the pattern 24 may be varied according to the second angle θ2. In other words, a difference D1 between the etch rate ER1 of the insulating layer 40 and the etch rate ER2 of the pattern 24 when the second angle θ2 is a relatively low angle may be greater than a difference D2 between the etch rate ER1 of the insulating layer 40 and the etch rate ER2 of the pattern 24 when the second angle θ2 is a relatively high angle (i.e., D1>D2). Therefore, the selective removal of the insulating layer 40 may be easier as the difference between the etch rate ER1 of the insulating layer 40 and the etch rate ER2 of the pattern 24 increases, i.e., when the difference is D1 rather than D2. Thus, the second ion beams IB2 may be irradiated at the relatively low angle with respect to the reference line S during the process of removing the insulating layer 40. In an embodiment, the second angle θ2 may range from about 0 degree to about 45 degrees, e.g., about 30 degree to about 40 degrees.

If the second ion beam IB2 includes the non-volatile element (e.g., argon ions) and the insulating source (e.g., oxygen ions and/or nitrogen ions), the etch rate of the pattern 24 by the second ion beam IB2 may be reduced by the insulating source, i.e., reduced from rate ER2 to rate ER2′. In other words, a difference between an etch rate ER1′ of the insulating layer 40 and an etch rate ER2′ of the pattern 24 by the second ion beam IB2 when the second ion beam IB2 includes the non-volatile element and the insulating source may be greater than the difference between the etch rate ER1 of the insulating layer 40 and the etch rate ER2 of the pattern 24 by the second ion beam IB2 when the second ion beam IB2 includes only the non-volatile element (i.e., D1′>D1, D2′<D2). That is, since the insulating source is added into the second ion source IS2, the selective removal of the insulating layer 40 may become easier.

According to embodiments, the etch residues 28 from etching the patterns 24 may be oxidized or nitrified using the first ion beams IB1 to form the insulating layer 40 on the sidewalls of the patterns 24, and the insulating layer 40 may be subsequently removed using the second ion beams IB2. For example, as the insulating layer 40 may include substantially the entirety of the etch residues 28 on the patterns 24, removal of the insulating layer 40 may include removal of substantial entirety of the etch residues 28 from the patterns 24. In this case, the first ion beams IB1 may be generated from the first ion source IS1 including an insulating source having a relatively high concentration, and the second ion beams IB2 may be generated from the second ion source IS2 including an insulating source having a relatively low concentration. Thus, the insulating layer 40 may be easily formed, and the selective removal of the insulating layer 40 may be easily performed. In addition, the first ion beams IB1 may be irradiated to the substrate 10 at a relatively high angle, so the insulating layer 40 may be formed to have a uniform thickness. Furthermore, the second ion beams IB2 may be irradiated to the substrate at a relatively low angle, so the selective removal of the insulating layer 40 may be easily performed.

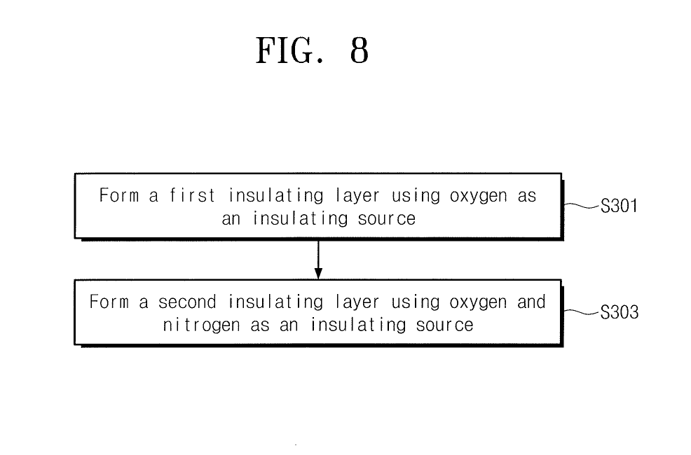

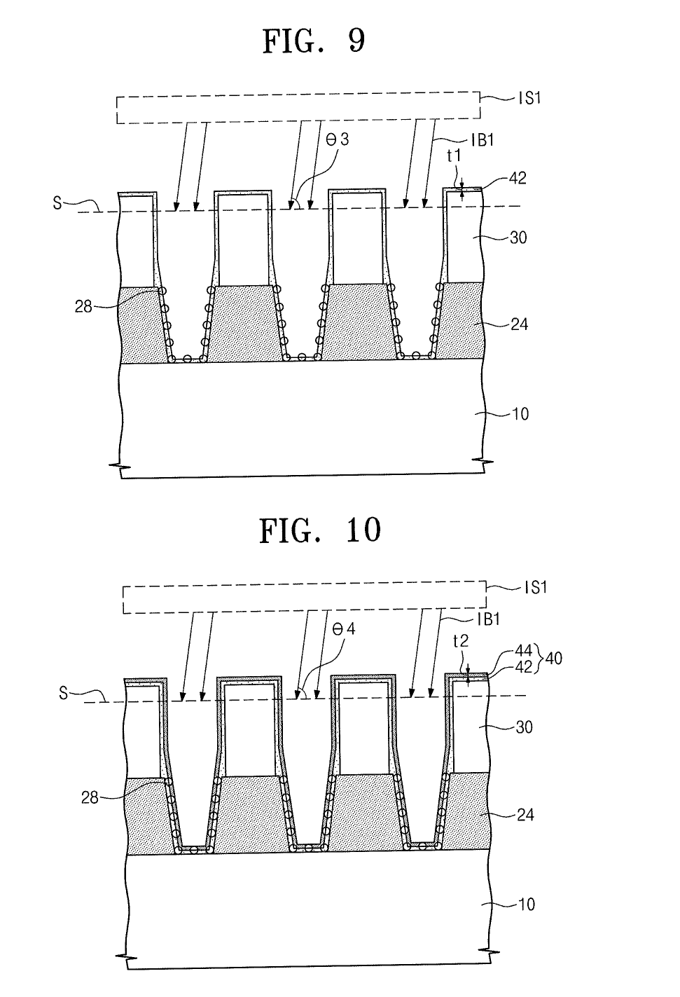

FIG. 8 is a flow chart illustrating an embodiment of operation S300 of FIG. 1, and FIGS. 9 and 10 are cross-sectional views illustrating stages in operation S300 of FIG. 1.

Referring to FIGS. 8 and 9, a first insulating layer 42 may be formed using oxygen as the insulating source (S301). The first insulating layer 42 may be formed on sidewalls of the patterns 24. The first insulating layer 42 may extend onto the surfaces of the mask patterns 30 and the substrate 10 between the patterns 24. According to the present embodiment, forming the first insulating layer 42 may include oxidizing at least a portion of the etch residues 28. A portion of each of the mask patterns 30 may also be oxidized during the oxidation of the etch residues 28.

The first insulating layer 42 may be formed using a sputtering method. In detail, the first ion beams IB1 may be provided to the substrate 10 having the patterns 24 thereon. The first ion beams IB1 may be generated from the first ion source IS1. According to the present embodiment, during the formation of the first insulating layer 42, the first ion source IS1 may include the insulating source, and the insulating source may be oxygen. At least a portion of the etch residues 28 may be oxidized by the first ion beams IB1 including the insulating source, and the portion of each of the mask patterns 30 may also be oxidized by the first ion beams IB1. The first ion source IS1 may further include a non-volatile element (e.g., argon). For example, the concentration of the insulating source in the first ion source IS1 may range from about 30 at % to about 50 at %.

The first ion beams IB1 may be irradiated to the surfaces of the substrate 10, the patterns 24, and the mask patterns 30 at a third angle θ3 with respect to the reference line S. As described with reference to FIG. 6, the first ion beams IB1 may be irradiated at a relatively high angle with respect to the reference line S, and thus, the first insulating layer 42 may be formed to have a uniform thickness t1. In an embodiment, the third angle θ3 may be in a range of about 80 degrees to about 90 degrees.

Referring to FIGS. 8 and 10, a second insulating layer 44 may be formed using oxygen and nitrogen as the insulating source (S303). The second insulating layer 44 may be formed on the first insulating layer 42. According to the present embodiment, forming the second insulating layer 44 may include oxidizing or nitrifying a remaining portion of the etch residues 28, e.g., the second insulating layer 44 may include oxidizing or nitrifying the etch residues 28 on the patterns 24 that were not oxidized during operation 5301. A portion of each of the mask patterns 30 may also be oxidized or nitrified during the oxidation or nitrification of the etch residues 28 in operation S303.

The second insulating layer 44 may be formed using a sputtering method. In detail, the first ion beams IB1 may be provided to the substrate 10 having the first insulating layer 42 thereon. The first ion beams IB1 may be generated from the first ion source IS1. According to the present embodiment, during the formation of the second insulating layer 44, the first ion source IS1 may include the insulating source, and the insulating source may be oxygen and nitrogen. A remaining portion of the etch residues 28 on the sidewalls of the patterns 24 may be oxidized or nitrified by the first ion beams IB1 including the insulating source, and a portion of each of the mask patterns 30 may also be oxidized or nitrified by the first ion beams IB1. The first ion source IS1 may further include a non-volatile element (e.g., argon). For example, a concentration of the insulating source in the first ion source IS1 may range from about 30 at % to about 50 at %.

The first ion beams IB1 may be irradiated to a surface of the first insulating layer 42 at a fourth angle θ4 with respect to the reference line S. As described with reference to FIG. 6, the first ion beams IB1 may be irradiated at a relatively high angle with respect to the reference line S, and thus, the second insulating layer 44 may be formed to have a uniform thickness t2. In an embodiment, the fourth angle θ4 may range from about 80 degrees to about 90 degrees.

According to the present embodiment, the insulating layer 40 formed using the first ion beams IB1 in the process S300 of FIG. 1 may include the first insulating layer 42 and the second insulating layer 44 which are sequentially stacked on the sidewalls of the patterns 24. A nitrogen concentration in the second insulating layer 44 may be higher than a nitrogen concentration in the first insulating layer 42.

According to the present embodiment, since the second insulating layer 44 is formed using both oxygen and nitrogen as the insulating source, it is possible to easily convert the etch residues 28 into an insulating material. In addition, since the first insulating layer 42 is formed using oxygen as the insulating source, it is possible to inhibit nitrogen from being diffused into the patterns 24 during the formation of the second insulating layer 44.

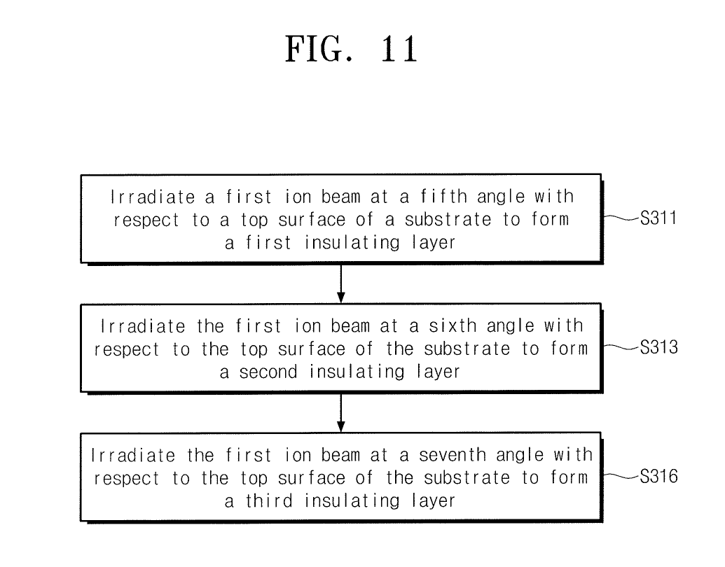

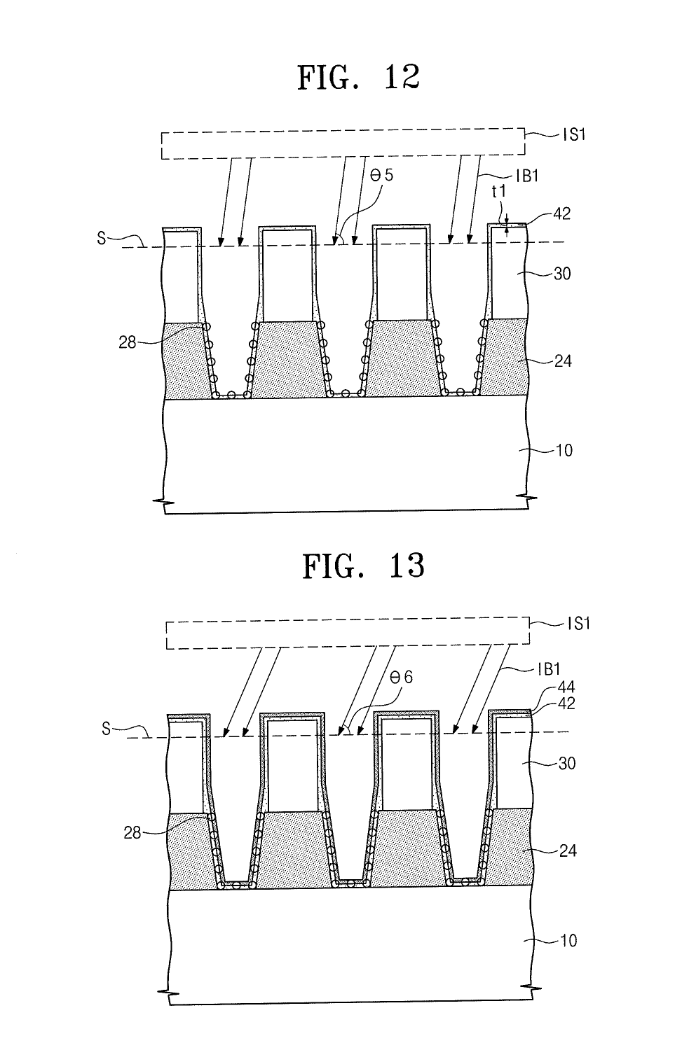

FIG. 11 is a flow chart illustrating an embodiment of operation S300 of FIG. 1, and FIGS. 12 to 14 are cross-sectional views illustrating stages in the operation S300 of FIG. 1.

Referring to FIGS. 11 and 12, first ion beams IB1 may be irradiated at a fifth angle θ5 with respect to the top surface of the substrate 10 (i.e., with respect to the reference line S) to form the first insulating layer 42 on the sidewalls of the patterns 24 (S311). The first insulating layer 42 may extend onto the surfaces of the mask patterns 30 and the substrate 10 between the patterns 24. Forming the first insulating layer 42 may include oxidizing or nitrifying at least a portion of the etch residues 28. A portion of each of the mask patterns 30 may also be oxidized or nitrified during the oxidation or nitrification of the etch residues 28.

The first insulating layer 42 may be formed using a sputtering method. In detail, the first ion beams IB1 may be provided to the substrate 10 having the patterns 24 thereon. The first ion beams IB1 may be generated from the first ion source IS1. The first ion source IS1 may include an insulating source, and the insulating source may include at least one of oxygen or nitrogen. At least a portion of the etch residues 28 may be oxidized or nitrified by the first ion beams IB1 including the insulating source, and a portion of each of the mask patterns 30 may also be oxidized or nitrified by the first ion beams IB1. The first ion source IS1 may further include a non-volatile element (e.g., argon). For example, a concentration of the insulating source in the first ion source IS1 may range from about 30 at % to about 50 at %.

The first ion beams IB1 may be irradiated to the surfaces of the substrate 10, the patterns 24, and the mask patterns 30 at the fifth angle θ5 with respect to the reference line S. As described with reference to FIG. 6, the first ion beams IB1 may be irradiated at a relatively high angle with respect to the reference line S, and thus, the first insulating layer 42 may be formed to have the uniform thickness t1. In an embodiment, the fifth angle θ5 may range from about 80 degrees to about 90 degrees.

Referring to FIGS. 11 and 13, the first ion beams IB1 may be irradiated at a sixth angle θ6 with respect to the top surface of the substrate 10 (i.e., the reference line S) to form the second insulating layer 44 on the first insulating layer 42 (S313). Forming the second insulating layer 44 may include oxidizing or nitrifying at least a portion of the etch residues 28. A portion of each of the mask patterns 30 may also be oxidized or nitrified during the oxidation or nitrification of the etch residues 28.

The second insulating layer 44 may be formed using a sputtering method. In detail, the first ion beams IB1 may be provided to the substrate 10 having the first insulating layer 42 thereon. The first ion beams IB1 may be generated from the first ion source IS1. The first ion source IS1 may include the insulating source, and the insulating source may include at least one of oxygen or nitrogen. At least a portion of the etch residues 28 may be oxidized or nitrified by the first ion beams IB1 including the insulating source, and the portion of each of the mask patterns 30 may also be oxidized or nitrified by the first ion beams IB1. The first ion source IS1 may further include a non-volatile element (e.g., argon). For example, a concentration of the insulating source in the first ion source IS1 may range from about 30 at % to about 50 at %.

The first ion beams IB1 may be irradiated to a surface of the first insulating layer 42 at the sixth angle θ6 with respect to the reference line S. The sixth angle θ6 may be smaller than the fifth angle θ5. As described with reference to FIG. 6, when the first ion beam IB1 is irradiated at a relatively low angle with respect to the reference line S, the insulating source of the first ion beam IB1 may penetrate deeper the first insulating layer 42 relative to an outer surface of the first insulating layer 42 into the inside thereof. Thus, if a portion of the etch residues 28 is not oxidized or nitrified, i.e., during operation S311, and remains on the sidewalls of the patterns 24 after the formation of the first insulating layer 42, the remaining portion of the etch residues 28 may be easily oxidized or nitrified during the formation of the second insulating layer 44 by the deeper ion beams. In other words, the first ion beams IB1 may be irradiated at the relatively low angle with respect to the reference line S during the formation of the second insulating layer 44, and thus the remaining portion of the etch residues 28 may be easily oxidized or nitrified. In an embodiment, the sixth angle θ6 may range from about 0 degree to about 45 degrees.

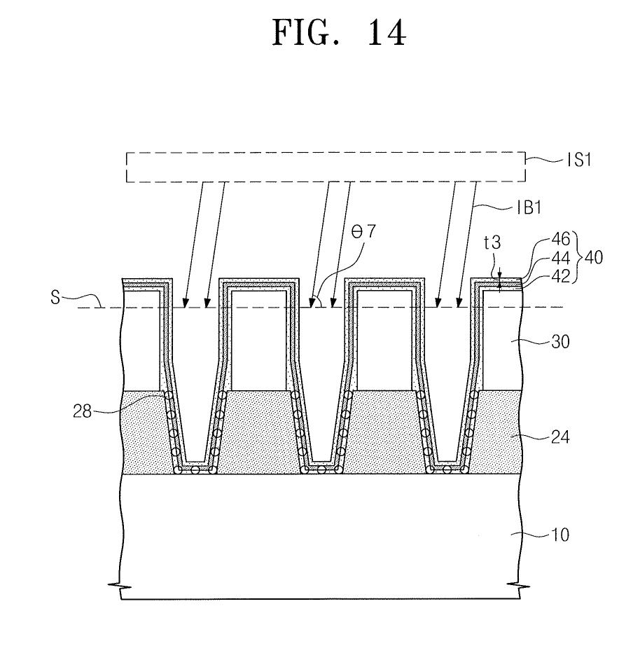

Referring to FIGS. 11 and 14, the first ion beams IB1 may be irradiated at a seventh angle θ7 with respect to the top surface of the substrate 10 (i.e., the reference line S) to form a third insulating layer 46 on the second insulating layer 44 (S316). Forming the third insulating layer 46 may include oxidizing or nitrifying the remaining portion of the etch residues 28, i.e., a portion of the etch residues 28 not oxidized or nitrified in operations S311 and S313. A portion of each of the mask patterns 30 may also be oxidized or nitrified during the oxidation or nitrification of the etch residues 28 in operation S316.

The third insulating layer 46 may be formed using a sputtering method. In detail, the first ion beams IB1 may be provided to the substrate 10 having the second insulating layer 44 thereon. The first ion beams IB1 may be generated from the first ion source IS1. The first ion source IS1 may include the insulating source, and the insulating source may include at least one of oxygen or nitrogen. The remaining portion of the etch residues 28 may be oxidized or nitrified by the first ion beams IB1 including the insulating source, and a portion of each of the mask patterns 30 may also be oxidized or nitrified by the first ion beams IB1. The first ion source IS1 may further include a non-volatile element (e.g., argon). For example, a concentration of the insulating source in the first ion source IS1 may range from about 30 at % to about 50 at %.

The first ion beams IB1 may be irradiated to a surface of the second insulating layer 44 at the seventh angle θ7 with respect to the reference line S. The seventh angle θ7 may be greater than the sixth angle θ6. The seventh angle θ7 may be substantially equal to the fifth angle θ5. The first ion beams IB1 may be irradiated at a relatively high angle with respect to the reference line S during the formation of the third insulating layer 46, as described with reference to FIG. 6, so the third insulating layer 46 may have a uniform thickness t3. In an embodiment, the seventh angle θ7 may range from about 80 degrees to about 90 degrees.

According to the present embodiment, the insulating layer 40 formed using the first ion beams IB1 in operation S300 of FIG. 1 may include the first insulating layer 42, the second insulating layer 44, and the third insulating layer 46 which are sequentially stacked on the sidewalls of the patterns 24. According to the present embodiment, since the second insulating layer 44 is formed by irradiating the first ion beams IB1 to the substrate 10 at a relatively low angle, the etch residues 28 may be easily converted into an insulating material. In addition, the first ion beams IB1 may be irradiated to the substrate 10 at a relatively high angle to form the first insulating layer 42 before the formation of the second insulating layer 44, so it is possible to inhibit the insulating source of the first ion beams IB1 from being diffused into the patterns 24 during the formation of the second insulating layer 44. Further, when the insulating layer 40 including a plurality of stacked insulating layers is removed, the second ion beams may be irradiated toward the substrate at a relatively low angle, e.g., at an angle lower than the fifth and seventh angles above, so the selective removal of the insulating layer may be easier.

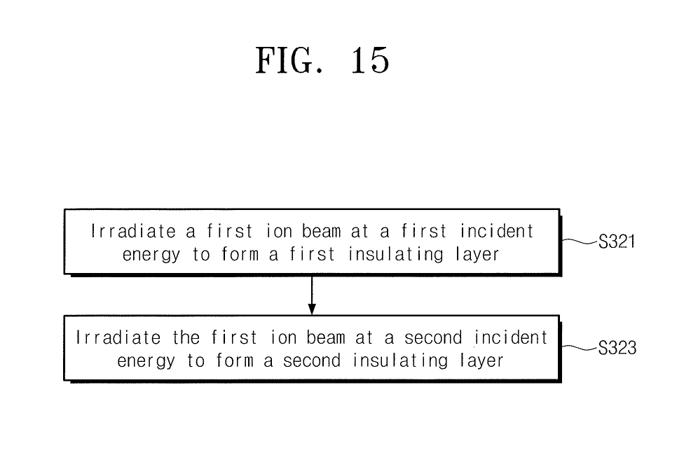

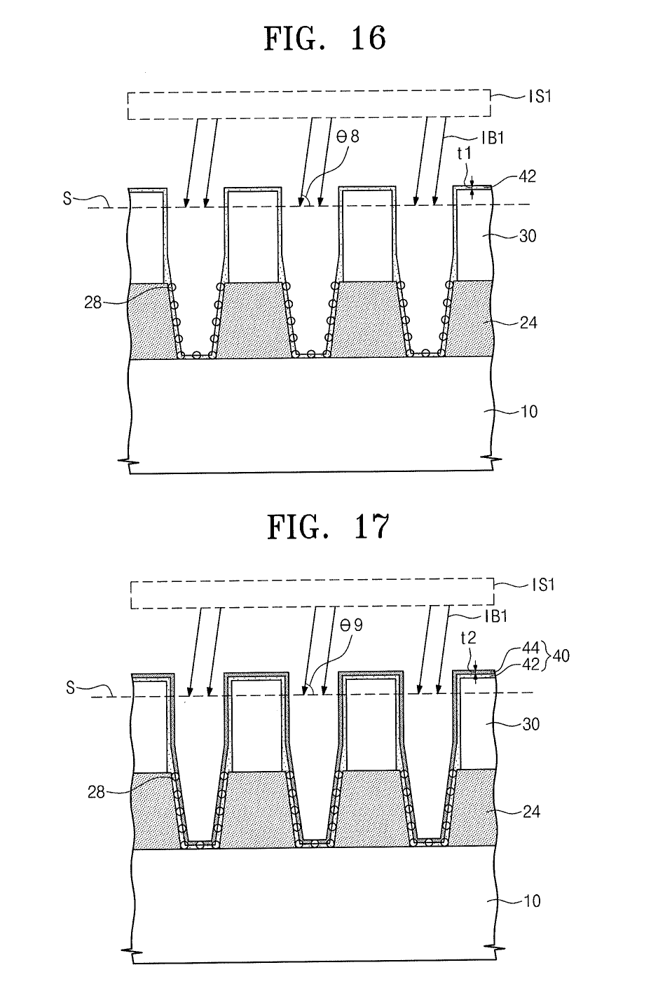

FIG. 15 is a flow chart illustrating an embodiment of operation S300 of FIG. 1, and FIGS. 16 and 17 are cross-sectional views illustrating stages in operation S300 of FIG. 1.

Referring to FIGS. 15 and 16, first ion beams IB1 may be irradiated to the substrate 10 at a first incident energy to form a first insulating layer 42 on the sidewalls of the patterns 24 (S321). The first insulating layer 42 may extend onto the surfaces of the mask patterns 30 and the substrate 10 between the patterns 24. According to the present embodiment, forming the first insulating layer 42 may include oxidizing or nitrifying at least a portion of the etch residues 28. A portion of each of the mask patterns 30 may also be oxidized or nitrified during the oxidation or nitrification of the etch residues 28.

The first insulating layer 42 may be formed using a sputtering method. In detail, the first ion beams IB1 may be provided to the substrate 10 having the patterns 24 thereon. The first ion beams IB1 may be generated from the first ion source IS1. The first ion source IS1 may include an insulating source, and the insulating source may include at least one of oxygen or nitrogen. At least a portion of the etch residues 28 may be oxidized or nitrified by the first ion beams IB1 including the insulating source, and a portion of each of the mask patterns 30 may also be oxidized or nitrified by the first ion beams IB1. The first ion source IS1 may further include a non-volatile element (e.g., argon). For example, a concentration of the insulating source in the first ion source IS1 may range from about 30 at % to about 50 at %.

The first ion beams IB1 may be irradiated to the surfaces of the substrate 10, the patterns 24, and the mask patterns 30 at an eighth angle θ8 with respect to the reference line S. As described with reference to FIG. 6, the first ion beams IB1 may be irradiated at a relatively high angle with respect to the reference line S, so the first insulating layer 42 may be formed to have the uniform thickness t1. In an embodiment, the eighth angle θ8 may range from about 80 degrees to about 90 degrees.

Referring to FIGS. 15 and 17, the first ion beams IB1 may be irradiated to the substrate 10 at a second incident energy to form a second insulating layer 44 on the first insulating layer 42 (S323). Forming the second insulating layer 44 may include oxidizing or nitrifying the remaining portion of the etch residues 28. A portion of each of the mask patterns 30 may also be oxidized or nitrified during the oxidation or nitrification of the remaining portion of the etch residues 28.

The second insulating layer 44 may be formed using a sputtering method. In detail, the first ion beams IB1 may be provided to the substrate 10 having the first insulating layer 42 thereon. The first ion beams IB1 may be generated from the first ion source IS1. The first ion source IS1 may include the insulating source, and the insulating source may include at least one of oxygen or nitrogen. The remaining portion of the etch residues 28 may be oxidized or nitrified by the first ion beams IB1 including the insulating source, and a portion of each of the mask patterns 30 may also be oxidized or nitrified by the first ion beams IB1. The first ion source IS1 may further include a non-volatile element (e.g., argon). For example, a concentration of the insulating source in the first ion source IS1 may range from about 30 at % to about 50 at %.

The first ion beams IB1 may be irradiated to a surface of the first insulating layer 42 at a ninth angle θ9 with respect to the reference line S. As described with reference to FIG. 6, the first ion beams IB1 may be irradiated at a relatively high angle with respect to the reference line S, so the second insulating layer 44 may be formed to have the uniform thickness t2. In an embodiment, the ninth angle θ9 may range from about 80 degrees to about 90 degrees.

According to the present embodiment, the second incident energy may be greater than the first incident energy. When the first ion beams IB1 are irradiated to the surfaces of the patterns 24 at the first incident energy which is relatively low, the insulating source of the first ion beams IB1 may shallowly penetrate the patterns 24 from the surfaces of the patterns 24 into the inside thereof. Thus, the first insulating layer 42 may be formed to have the uniform thickness t1. When the first ion beams IB1 are irradiated to the first insulating layer 42 at the second incident energy which is higher that the first incident energy, the insulating source of the first ion beams IB1 may deeply penetrate the first insulating layer 42 from the surface of the first insulating layer 42 into the inside of thereof, e.g., the first ion beams IB1 may penetrate through the first insulating layer 42. Thus, if a portion of the etch residues 28 is not oxidized or nitrified but remains on the sidewalls of the patterns 24, after the formation of the first insulating layer 42, the remaining portion of the etch residues 28 may be easily oxidized or nitrified during the formation of the second insulating layer 44. For example, the first incident energy may be 100 eV or less, and the second incident energy may be 400 eV or more.

According to the present embodiment, the insulating layer 40 formed using the first ion beams IB1 in operation S300 of FIG. 1 may include the first insulating layer 42 and the second insulating layer 44, which are sequentially stacked on the sidewalls of the patterns 24. According to the present embodiment, the first ion beams IB1 may be irradiated to the substrate 10 at the second incident energy, which is higher that the first incident energy, to form the second insulating layer 44, so the remaining portion of the etch residues 28 may be easily converted into an insulating material. In addition, the first ion beams IB1 may be irradiated to the substrate 10 at the first incident energy, which is relatively low, to form the first insulating layer 42 before the formation of the second insulating layer 44, so it is possible to inhibit the insulating source of the first ion beams IB1 from being diffused into the patterns 24.

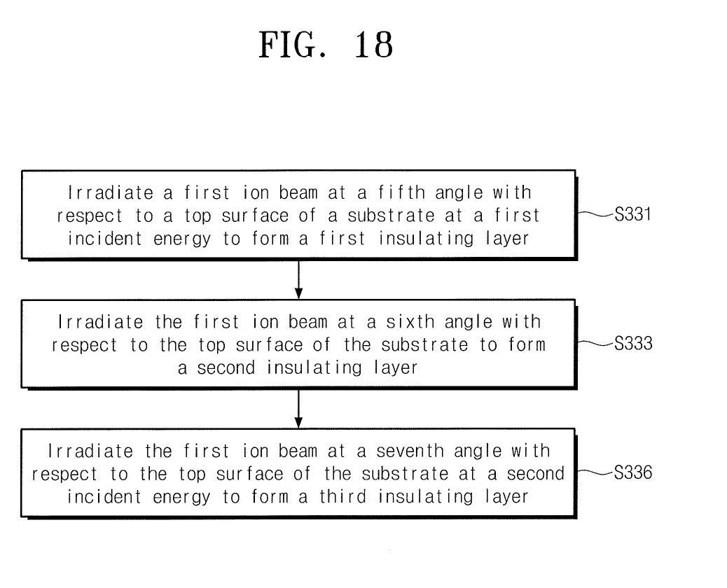

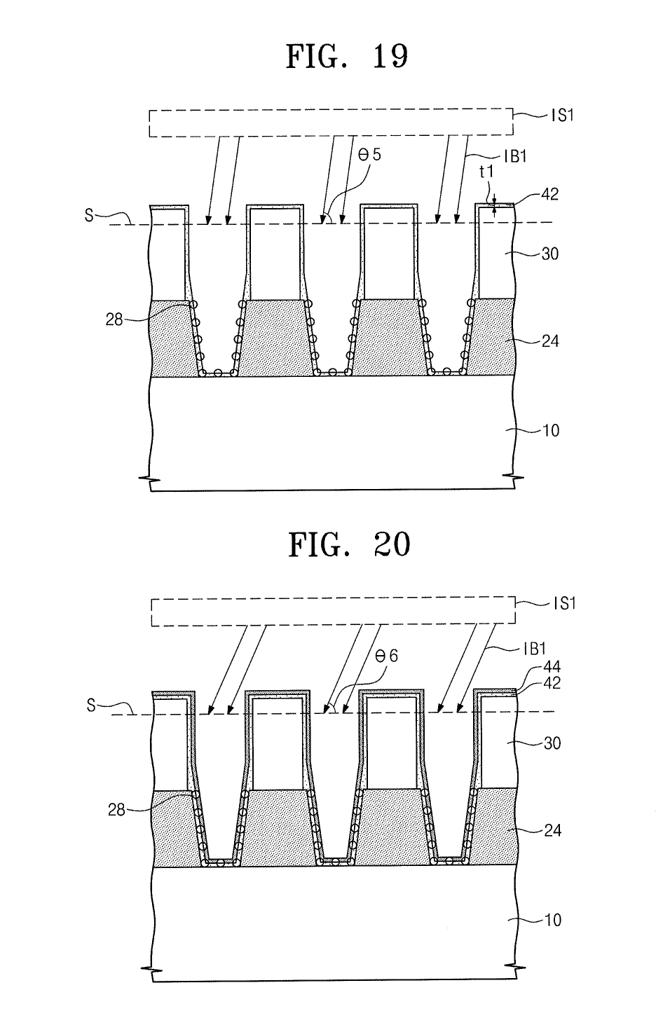

FIG. 18 is a flow chart illustrating an embodiment of operation S300 of FIG. 1, and FIGS. 19 to 21 are cross-sectional views illustrating stages in operation S300 of FIG. 1.

Referring to FIGS. 18 and 19, the first ion beams IB1 may be irradiated at the fifth angle θ5 with respect to the top surface of the substrate 10 (e.g., the reference line S) at the first incident energy to form the first insulating layer 42 on the sidewalls of the patterns 24 (S331). The first insulating layer 42 may extend on the surfaces of the mask patterns 30 and the substrate 10 disposed between the patterns 24. Forming the first insulating layer 42 may include oxidizing or nitrifying at least a portion of the etch residues 28. A portion of each of the mask patterns 30 may also be oxidized or nitrified during the oxidation or nitrification of the etch residues 28.

The first insulating layer 42 may be formed using a sputtering method. In detail, the first ion beams IB1 may be provided to the substrate 10 having the patterns 24 thereon. The first ion beams IB1 may be generated from the first ion source IS1. The first ion source IS1 may include the insulating source, and the insulating source may include at least one of oxygen or nitrogen. At least a portion of the etch residues 28 may be oxidized or nitrified by the first ion beams IB1 including the insulating source, and the portion of each of the mask patterns 30 may also be oxidized or nitrified by the first ion beams IB1. The first ion source IS1 may further include the non-volatile element (e.g., argon). For example, the concentration of the insulating source in the first ion source IS1 may range from about 30 at % to about 50 at %.

The first ion beams IB1 may be irradiated to the surfaces of the substrate 10, the patterns 24, and the mask patterns 30 at the fifth angle θ5 with respect to the reference line S. As described with reference to FIG. 6, the first ion beams IB1 may be irradiated at the relatively high angle with respect to the reference line S, so the first insulating layer 42 may be formed to have the uniform thickness t1. In an embodiment, the fifth angle θ5 may range from about 80 degrees to about 90 degrees.

In addition, the first ion beams IB1 may be irradiated to the surfaces of the patterns 24 at the first incident energy, which is relatively low, so the insulating source of the first ion beams IB1 may shallowly penetrate the patterns 24 from the surfaces of the patterns 24 into the inside thereof. As a result, the first insulating layer 42 may be formed to have the uniform thickness t1.

Referring to FIGS. 18 and 20, the first ion beams IB1 may be irradiated at the sixth angle θ6 with respect to the top surface of the substrate 10 (i.e., the reference line S) to form the second insulating layer 44 on the first insulating layer 42 (S333). Forming the second insulating layer 44 may include oxidizing or nitrifying at least a portion of the etch residues 28. A portion of each of the mask patterns 30 may also be oxidized or nitrified during the oxidation or nitrification of the etch residues 28.

The second insulating layer 44 may be formed using a sputtering method. In detail, the first ion beams IB1 may be provided to the substrate 10 having the first insulating layer 42 thereon. The first ion beams IB1 may be generated from the first ion source IS1. The first ion source IS1 may include the insulating source, and the insulating source may include at least one of oxygen or nitrogen. At least a portion of the etch residues 28 may be oxidized or nitrified by the first ion beams IB1 including the insulating source, and the portion of each of the mask patterns 30 may also be oxidized or nitrified by the first ion beams IB1. The first ion source IS1 may further include the non-volatile element (e.g., argon). For example, the concentration of the insulating source in the first ion source IS1 may range from about 30 at % to about 50 at %.

The first ion beams IB1 may be irradiated to the surface of the first insulating layer 42 at the sixth angle θ6 with respect to the reference line S. The sixth angle θ6 may be smaller than the fifth angle θ5. As described with reference to FIG. 6, when the first ion beam IB1 is irradiated at a relatively low angle with respect to the reference line S, the insulating source of the first ion beam IB1 may deeply penetrate the first insulating layer 42 from the surface of the first insulating layer 42 into the inside thereof. Thus, if a portion of the etch residues 28 is not oxidized or nitrified but remains on the sidewalls of the patterns 24 after the formation of the first insulating layer 42, the remaining portion of the etch residues 28 may be easily oxidized or nitrified during the formation of the second insulating layer 44. In other words, the first ion beams IB1 may be irradiated at the relatively low angle with respect to the reference line S during the formation of the second insulating layer 44, so the remaining portion of the etch residues 28 may be easily oxidized or nitrified. In an embodiment, the sixth angle θ6 may range from about 0 degree to about 45 degrees.

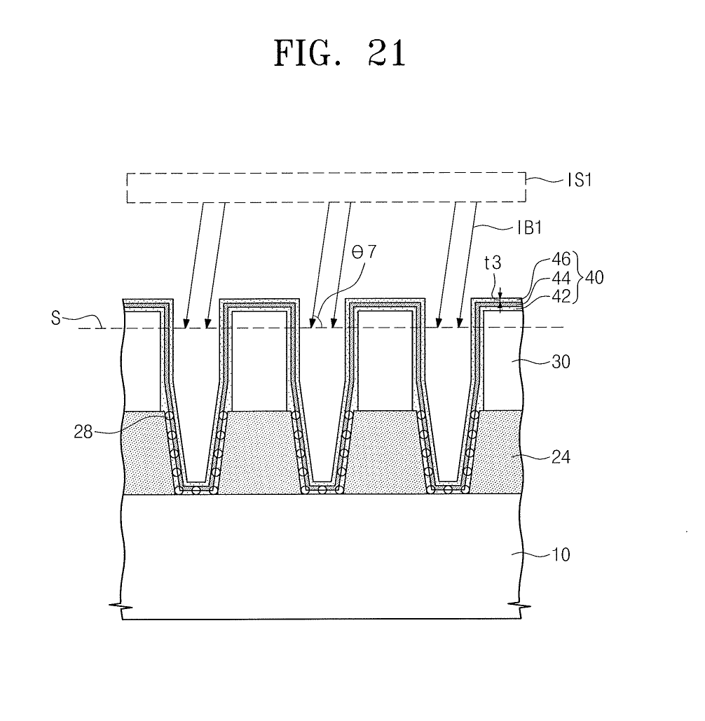

Referring to FIGS. 18 and 21, the first ion beams IB1 may be irradiated at the seventh angle θ7 with respect to the top surface of the substrate 10 (i.e., the reference line S) at the second incident energy to form a third insulating layer 46 on the second insulating layer 44 (S336). Forming the third insulating layer 46 may include oxidizing or nitrifying the rest portion of the etch residues 28. A portion of each of the mask patterns 30 may also be oxidized or nitrified during the oxidation or nitrification of the etch residues 28.

The third insulating layer 46 may be formed using a sputtering method. In detail, the first ion beams IB1 may be provided to the substrate 10 having the second insulating layer 44 thereon. The first ion beams IB1 may be generated from the first ion source IS1. The first ion source IS1 may include the insulating source, and the insulating source may include at least one of oxygen or nitrogen. The rest portion of the etch residues 28 may be oxidized or nitrified by the first ion beams IB1 including the insulating source, and the portion of each of the mask patterns 30 may also be oxidized or nitrified by the first ion beams IB1. The first ion source IS1 may further include the non-volatile element (e.g., argon). For example, the concentration of the insulating source in the first ion source IS1 may range from about 30 at % to about 50 at %.

The first ion beams IB1 may be irradiated to a surface of the second insulating layer 44 at the seventh angle θ7 with respect to the reference line S. The seventh angle θ7 may be greater than the sixth angle θ6. The seventh angle θ7 may be substantially equal to the fifth angle θ5. The first ion beams IB1 may be irradiated at a relatively high angle with respect to the reference line S during the formation of the third insulating layer 46, as described with reference to FIG. 6, so the third insulating layer 46 may have the uniform thickness t3. In an embodiment, the seventh angle θ7 may range from about 80 degrees to about 90 degrees.

In addition, when the first ion beams IB1 are irradiated to the second insulating layer 44 at the second incident energy, which is relatively high, the insulating source of the first ion beams IB1 may deeply penetrate the second insulating layer 44 from the surface of the second insulating layer 44 into the inside thereof. Thus, if a portion of the etch residues 28 is not oxidized or nitrified but remains on the sidewalls of the patterns 24 after the formation of the second insulating layer 44, the remaining portion of the etch residues 28 may be easily oxidized or nitrified during the formation of the third insulating layer 46.

In the present embodiment, the insulating layer 40 formed using the first ion beams IB1 in operation S300 of FIG. 1 may include the first insulating layer 42, the second insulating layer 44, and the third insulating layer 46 which are sequentially stacked on the sidewalls of the patterns 24. According to the present embodiment, the first ion beams IB1 may be irradiated to the substrate 10 at the relatively low angle to form the second insulating layer 44, and the first ion beams IB1 may be irradiated to the substrate 10 at the second incident energy relatively high to form the third insulating layer 46. Thus, the etch residues 28 may be easily converted into an insulating material. In addition, before the formation of the second insulating layer 44, the first ion beams IB1 may be irradiated to the substrate 10 at the relatively high angle and at the first incident energy, which is relatively low, to form the first insulating layer 42. Thus, it is possible to inhibit the insulating source of the first ion beams IB1 from being diffused into the patterns 24 during the formation of the second and third insulating layers 44 and 46.

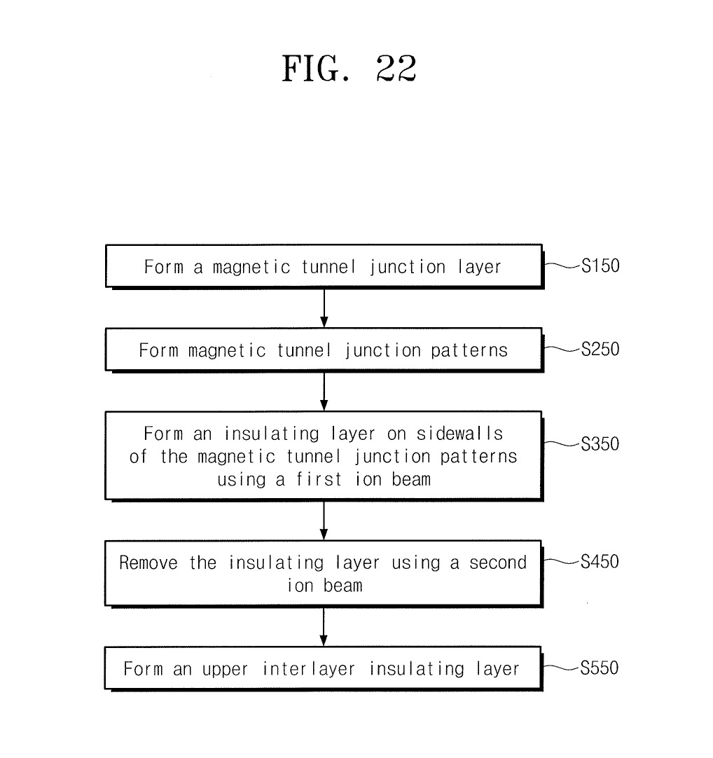

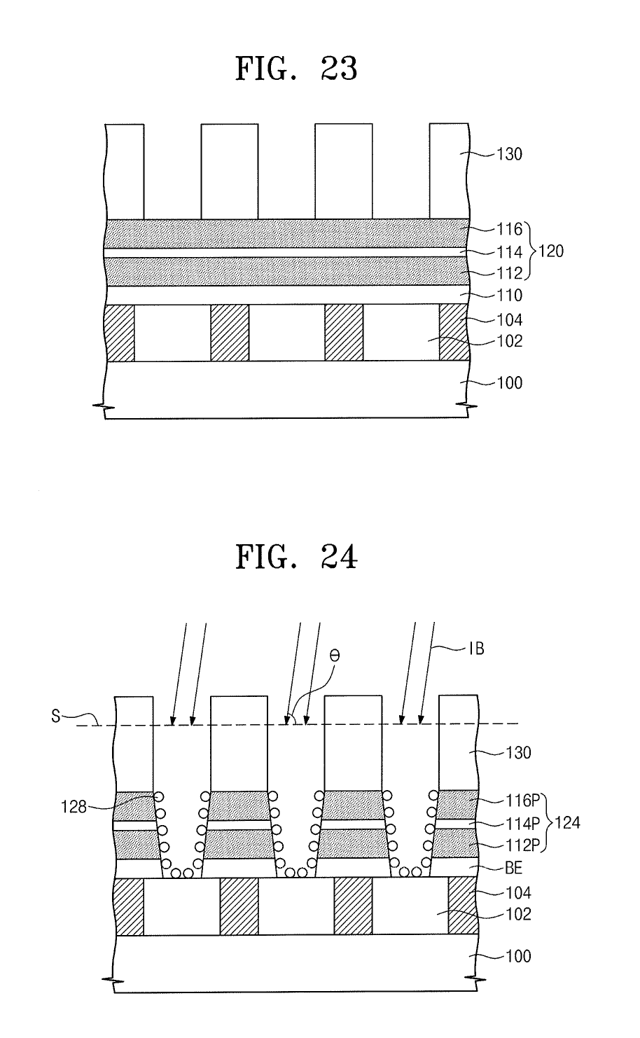

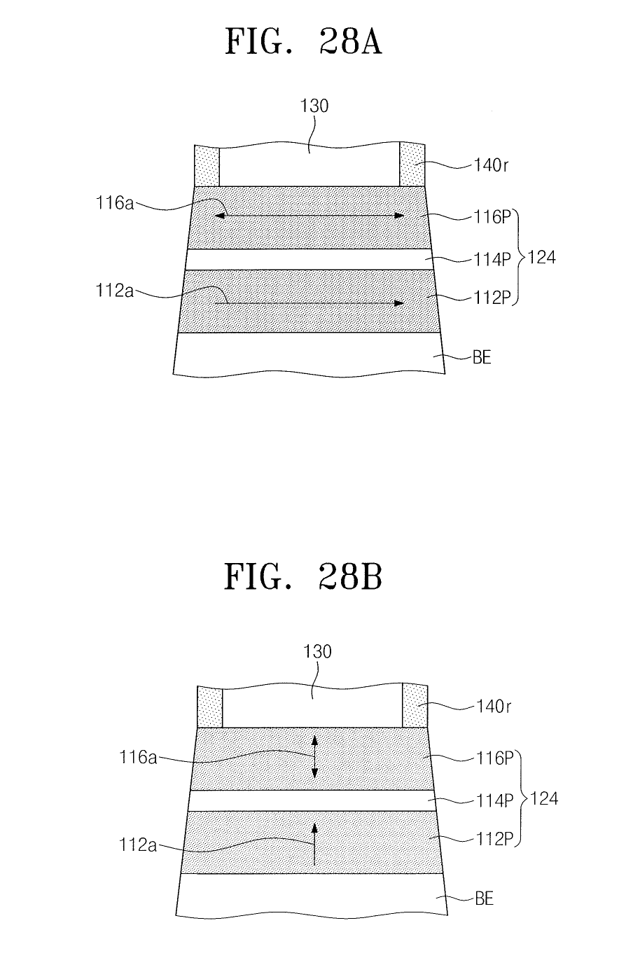

FIG. 22 is a flow chart illustrating a method of manufacturing a magnetic memory device according to an embodiment. FIGS. 23 to 27 are cross-sectional views illustrating stages in a method of manufacturing a magnetic memory device according to an embodiment. FIG. 28A is a cross-sectional view illustrating a magnetic tunnel junction (MTJ) pattern according to an embodiment. FIG. 28B is a cross-sectional view illustrating a MTJ pattern according to an embodiment.

Referring to FIGS. 22 and 23, a lower interlayer insulating layer 102 may be formed on a substrate 100. The substrate 100 may include a semiconductor substrate. For example, the substrate 100 may include a silicon substrate, a germanium substrate, or a silicon-germanium substrate. According to an embodiment, selection components (not shown) may be formed on the substrate 100, and the lower interlayer insulating layer 102 may be formed to cover the selection components. For example, the selection components may be field effect transistors. In another example, the selection components may be diodes. The lower interlayer insulating layer 102 may be formed of a single or multi-layer including an oxide (e.g., silicon oxide), a nitride (e.g., silicon nitride), and/or an oxynitride (e.g., silicon oxynitride).

Lower contact plugs 104 may be formed in the lower interlayer insulating layer 102. Each of the lower contact plugs 104 may penetrate the lower interlayer insulating layer 102 so as to be electrically connected to one terminal of a corresponding one of the selection components. The lower contact plugs 104 may include at least one of a doped semiconductor material (e.g., doped silicon), a metal (e.g., tungsten, titanium, and/or tantalum), a conductive metal nitride (e.g., titanium nitride, tantalum nitride, and/or tungsten nitride), or a metal-semiconductor compound (e.g., a metal silicide).

A magnetic tunnel junction layer 120 may be formed on the lower interlayer insulating layer 102 (S150). A bottom electrode layer 110 may be formed between the lower interlayer insulating layer 102 and the magnetic tunnel junction layer 120. The bottom electrode layer 110 may include a conductive metal nitride, e.g., titanium nitride and/or tantalum nitride. The bottom electrode layer 110 may include a material (e.g., ruthenium (Ru)) assisting crystal growth of magnetic layers constituting the magnetic tunnel junction layer 120. The bottom electrode layer 110 may be formed by, e.g., a sputtering process, a chemical vapor deposition (CVD) process, or an atomic layer deposition (ALD) process.

The magnetic tunnel junction layer 120 may include a first magnetic layer 112, a tunnel barrier layer 114, and a second magnetic layer 116 which are sequentially stacked on the bottom electrode layer 110. One of the first and second magnetic layers 112 and 116 may correspond to a reference layer that has a magnetization direction fixed in one direction, and the other of the first and second magnetic layers 112 and 116 may correspond to a free layer that has a magnetization direction changeable to be parallel or anti-parallel to the fixed magnetization direction of the reference layer.

In an embodiment, the magnetization directions of the reference layer and the free layer may be substantially perpendicular to an interface between the tunnel barrier layer 114 and the second magnetic layer 116. In this case, each of the reference layer and the free layer may include at least one of a perpendicular magnetic material (e.g., CoFeTb, CoFeGd, or CoFeDy), a perpendicular magnetic material having a L1₀ structure, CoPt having a hexagonal close packed (HCP) crystal structure, or a perpendicular magnetic structure. The perpendicular magnetic material having the L1₀ structure may include at least one of, e.g., FePt having the L1₀ structure, FePd having the L1₀ structure, CoPd having the L1₀ structure, or CoPt having the L1₀ structure. The perpendicular magnetic structure may include magnetic layers and non-magnetic layers which are alternately and repeatedly stacked. For example, the perpendicular magnetic structure may include at least one of, e.g., (Co/Pt)n, (CoFe/Pt)n, (CoFe/Pd)n, (Co/Pd)n, (Co/Ni)n, (CoNi/Pt)n, (CoCr/Pt)n, or (CoCr/Pd)n, where “n” denotes the number of bilayers. Here, the reference layer may be thicker than the free layer, and/or a coercive force of the reference layer may be greater than that of the free layer.

In an embodiment, the magnetization directions of the reference layer and the free layer may be substantially parallel to the interface between the tunnel barrier layer 114 and the second magnetic layer 116. In this case, each of the reference layer and the free layer may include a ferromagnetic material. The reference layer may further include an anti-ferromagnetic material that is used to fix a magnetization direction of the ferromagnetic material included in the reference layer.

The tunnel barrier layer 114 may include at least one of e.g., a magnesium oxide (MgO) layer, a titanium oxide (TiO) layer, an aluminum oxide (AlO) layer, a magnesium-zinc oxide (MgZnO) layer, or a magnesium-boron oxide (MgBO) layer.

Each of the first magnetic layer 112, the tunnel barrier layer 114 and the second magnetic layer 116 may be formed by a physical vapor deposition (PVD) process or a CVD process.

Conductive mask patterns 130 may be formed on the magnetic tunnel junction layer 120. The conductive mask patterns 130 may include at least one of, e.g., tungsten, titanium, tantalum, aluminum, or metal nitrides (e.g., titanium nitride and tantalum nitride). The conductive mask patterns 130 may define regions where magnetic tunnel junction patterns to be described later will be formed.

Referring to FIGS. 22 and 24, the magnetic tunnel junction layer 120 may be etched using the conductive mask patterns 130 as an etch masks to form magnetic tunnel junction patterns 124 (S250). The etching process may be performed using a sputtering method. In more detail, ion beams IB may be provided to the substrate 100 having the conductive mask patterns 130 thereon, during the etching process. The ion beams IB may include, e.g., argon ions (Ar+). The ion beams IB may be irradiated to a surface of the magnetic tunnel junction layer 120 at a predetermined angle θ with respect to the reference line S parallel to a top surface of the substrate 100.

The magnetic tunnel junction layer 120 may be etched by the etching process to form the magnetic tunnel junction patterns 124 spaced apart from each other on the substrate 100. In addition, the bottom electrode layer 110 may also be etched by the etching process, so bottom electrodes BE spaced apart from each other may be formed on the substrate 100. The bottom electrodes BE may be electrically connected to the lower contact plugs 104 formed in the interlayer insulating layer 102, respectively. According to an embodiment, a bottom surface of each of the bottom electrodes BE may be in contact with a top surface of a corresponding one of the lower contact plugs 104. The magnetic tunnel junction patterns 124 may be formed on the bottom electrodes BE, respectively. Each of the magnetic tunnel junction patterns 124 may include a first magnetic pattern 112P, a tunnel barrier 114P, and a second magnetic pattern 116P which are sequentially stacked on each of the bottom electrodes BE.

In an embodiment, as illustrated in FIG. 28A, magnetization directions 112a and 116a of the first and second magnetic patterns 112P and 116P may be substantially parallel to a contact surface of the tunnel barrier 114P and the second magnetic pattern 116P. In FIG. 28A, the first magnetic pattern 112P is a reference pattern and the second magnetic pattern 116P is a free pattern. However, embodiments are not limited thereto. Unlike FIG. 28A, the first magnetic pattern 112P may be the free pattern and the second magnetic pattern 116P may be the reference pattern. The reference pattern may be thicker than the free pattern, or a coercive force of the reference pattern may be greater than that of the free pattern.

Each of the first and second magnetic patterns 112P and 116P having the parallel magnetization directions 112a and 116a may include a ferromagnetic material. The first magnetic pattern 112P corresponding to the reference pattern may further include an anti-ferromagnetic material used to fix a magnetization direction of the ferromagnetic material included in the first magnetic pattern 112P.

In an embodiment, as illustrated in FIG. 28B, magnetization directions 112a and 116a of the first and second magnetic patterns 112P and 116P may be substantially perpendicular to the contact surface of the tunnel barrier 114P and the second magnetic pattern 116P. In FIG. 28B, the first magnetic pattern 112P is a reference pattern and the second magnetic pattern 116P is a free pattern. However, embodiments are not limited thereto. Unlike FIG. 28B, the first magnetic pattern 112P may be the free pattern and the second magnetic pattern 116P may be the reference pattern.

Each of the first and second magnetic patterns 112P and 116P having the perpendicular magnetization directions 112a and 116a may include at least one of a perpendicular magnetic material (e.g., CoFeTb, CoFeGd, or CoFeDy), a perpendicular magnetic material having a L1₀ structure, CoPt having a HCP crystal structure, or a perpendicular magnetic structure. The perpendicular magnetic material having the L1₀ structure may include at least one of, e.g., FePt having the L1₀ structure. FePd having the L1₀ structure, CoPd having the L1₀ structure, or CoPt having the L1₀ structure. The perpendicular magnetic structure may include magnetic layers and non-magnetic layers which are alternately and repeatedly stacked. For example, the perpendicular magnetic structure may include at least one of, e.g., (Co/Pt)n, (CoFe/Pt)n, (CoFe/Pd)n, (Co/Pd)n, (Co/Ni)n, (CoNi/Pt)n, (CoCr/Pt)n, or (CoCr/Pd)n, where “n” denotes the number of bilayers.

During the etching process, etch residues 128 generated from the conductive mask patterns 130 and the magnetic tunnel junction layer 120 may be re-deposited on sidewalls of the magnetic tunnel junction patterns 124 and the substrate 100 (e.g., the lower interlayer insulating layer 102) disposed between the magnetic tunnel junction patterns 124. The etch residues 128 may include a conductive material. For example, the etch residues 128 may include a metal element. If the etch residues 128 remain on the sidewalls of the magnetic tunnel junction patterns 124, an electrical short may be caused between the first magnetic pattern 112P and the second magnetic pattern 116P of each of the magnetic tunnel junction patterns 124.

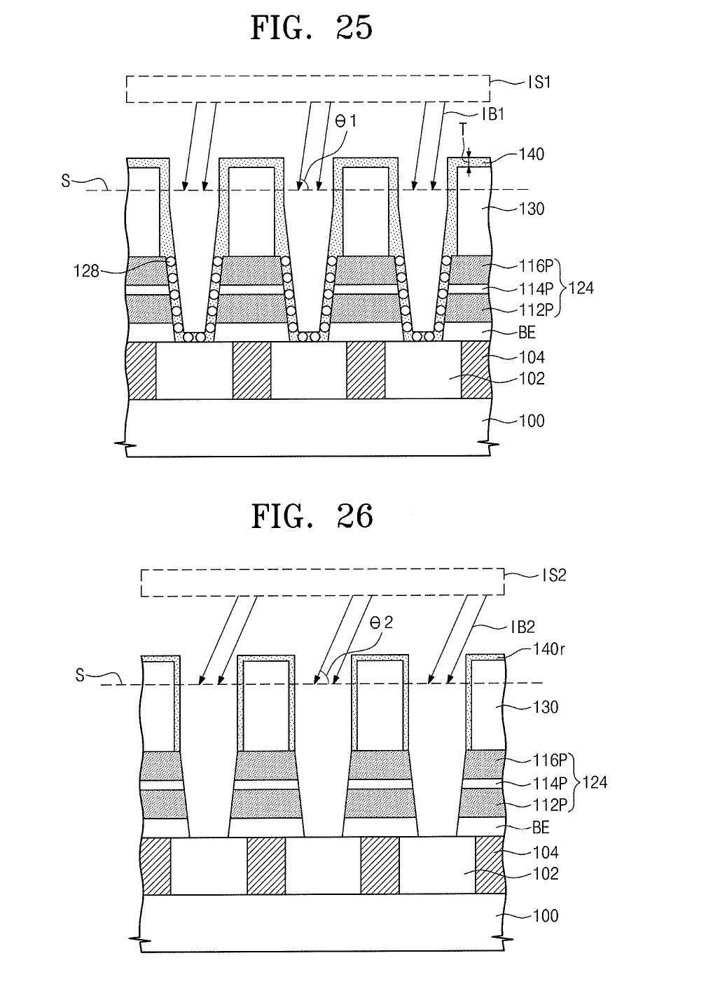

Referring to FIGS. 22 and 25, an insulating layer 140 may be formed on the sidewalls of the magnetic tunnel junction patterns 124 using the first ion beams IB1 (S350). The insulating layer 140 may extend onto surfaces of the conductive mask patterns 130 and the substrate 100 (e.g., the lower interlayer insulating layer 102) between the magnetic tunnel junction patterns 124. Forming the insulating layer 140 may include oxidizing or nitrifying the etch residues 128. A portion of each of the conductive mask patterns 130 may also be oxidized or nitrified during the oxidation or nitrification of the etch residues 128.

The insulating layer 140 may be formed using a sputtering method. In detail, the first ion beams IB1 may be provided to the substrate 10 having the magnetic tunnel junction patterns 124 thereon. The first ion beams IB1 may be generated from the first ion source IS1. The first ion source IS1 may include an insulating source, and the insulating source may include at least one of oxygen or nitrogen. The etch residues 128 may be oxidized or nitrified by the first ion beams IB1 including the insulating source, and a portion of each of the conductive mask patterns 130 may also be oxidized or nitrified by the first ion beams IB1 including the insulating source. The first ion source IS1 may further include a non-volatile element (e.g., argon). For example, a concentration of the insulating source in the first ion source IS1 may range from about 30 at % to about 50 at %.

The first ion beams IB1 may be irradiated to the surfaces of the conductive mask patterns 130, the surfaces of the magnetic tunnel junction patterns 124, and a surface of the substrate 100 (e.g., a surface of the interlayer insulating layer 102) at the first angle θ1 with respect to the reference line S. As described with reference to FIG. 6, the first ion beams IB1 may be irradiated at a relatively high angle with respect to the reference line S, so the insulating layer 140 may be formed to have a uniform thickness T. In an embodiment, the first angle θ1 may range from about 80 degrees to about 90 degrees. However, embodiments are not limited to the above, e.g., the insulating layer 140 in FIG. 25 may be formed in accordance with any of the embodiments of FIGS. 1-21 described above.

Referring to FIGS. 22 and 26, the insulating layer 140 may be removed using second ion beams IB2 (S450). The insulating layer 140 may be removed to expose the sidewalls of the magnetic tunnel junction patterns 124 and the substrate 100 (e.g., the lower interlayer insulating layer 102) between the magnetic tunnel junction patterns 124. According to an embodiment, residual portions 140r of the insulating layer 140 may not be removed but may remain on the conductive mask patterns 130.

The insulating layer 140 may be removed using a sputtering method. In detail, the second ion beams IB2 may be provided to the substrate 10 having the insulating layer 140 thereon. The second ion beams IB2 may be generated from the second ion source IS2. The second ion source IS2 may include an insulating source, and the insulating source of the second ion source IS2 may include at least one of oxygen or nitrogen. The second ion source IS2 may further include a non-volatile element (e.g., argon). A concentration of the insulating source in the second ion source IS2 may be different from the concentration of the insulating source in the first ion source IS1. In an embodiment, the concentration of the insulating source in the second ion source IS2 may be lower than the concentration of the insulating source in the first ion source IS1. As described with reference to FIG. 7, since the insulating source is added into the second ion source IS2, the selective removal of the insulating layer 140 may be easily performed. For example, the concentration of the insulating source in the second ion source IS2 may range from about 0 at % to about 10 at %.

The second ion beams IB2 may be irradiated to a surface of the insulating layer 140 at the second angle θ2 with respect to the reference line S. The second angle θ2 may be different from the first angle θ1. In an embodiment, the second angle θ2 may be smaller than the first angle θ1. As described with reference to FIG. 7, the second ion beams IB2 may be irradiated at a relatively low angle with respect to the reference line S, so the selective removal of the insulating layer 140 may be easily performed. For example, the second angle θ2 may range from about 0 degree to about 45 degrees.

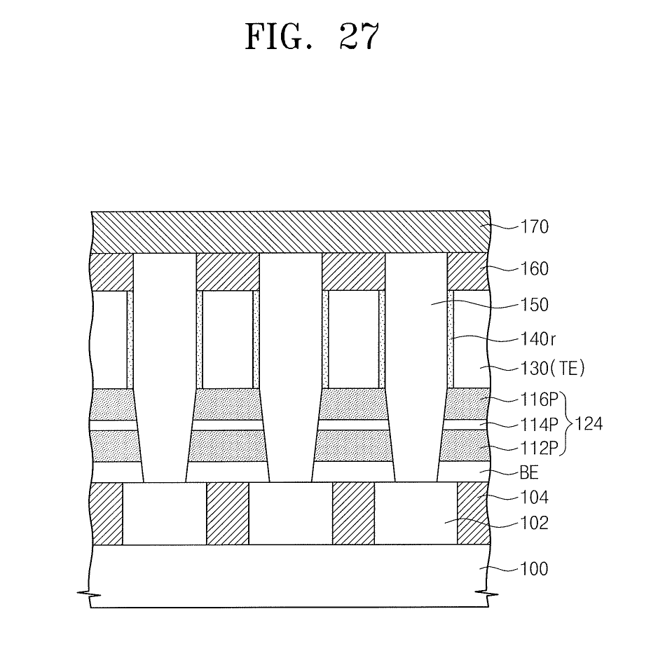

Referring to FIGS. 22 and 27, an upper interlayer insulating layer 150 may be formed on the lower interlayer insulating layer 102 to cover the bottom electrodes BE, the magnetic tunnel junction patterns 124, and the conductive mask patterns 130 (S550). The upper interlayer insulating layer 150 may be a single layer or a multi-layer. For example, the upper interlayer insulating layer 150 may include an oxide layer (e.g., a silicon oxide layer), a nitride layer (e.g., a silicon nitride layer), and/or an oxynitride layer (e.g., a silicon oxynitride layer).

The conductive mask patterns 130 may function as top electrodes TE that are provided on the magnetic tunnel junction patterns 124, respectively. Upper contact plugs 160 may be formed in the upper interlayer insulating layer 150 so as to be connected to the top electrodes TE, respectively. In an embodiment, forming the upper contact plugs 160 may include forming contact holes respectively exposing the top electrodes TE in the upper interlayer insulating layer 150, and forming the upper contact plugs 160 in the contact holes, respectively. In this case, upper portions of the residual portions 140r of the insulating layer 140, which remain on top surfaces of the top electrodes TE, respectively, may be removed by an etching process for forming the contact holes. The residual portions 140r of the insulating layer 140 may partially remain, e.g., only, on sidewalls of the top electrodes TE after the formation of the contact holes.

An interconnection 170 may be formed on the upper interlayer insulating layer 150. The interconnection 170 may extend in one direction and may be electrically connected to the magnetic tunnel junction patterns 124 arranged along the one direction. Each of the magnetic tunnel junction patterns 124 may be electrically connected to the interconnection 170 through the top electrode TE and the upper contact plug 160 which are disposed on each of the magnetic tunnel junction patterns 124. In an embodiment, the interconnection 170 may function as a bit line.

Hereinafter, structural features of the magnetic memory device manufactured according to an embodiment will be described with reference to FIG. 27.

Referring again to FIG. 27, a lower interlayer insulating layer 102 may be provided on the substrate 100. Selection components may be provided on the substrate 100, and the lower interlayer insulating layer 102 may cover the selection components. The selection components may be, e.g., field effect transistors or diodes. The lower contact plugs 104 may be provided in the lower interlayer insulating layer 102. Each of the lower contact plugs 104 may penetrate the lower interlayer insulating layer 104 so as to be electrically connected to one terminal of a corresponding one of the selection components.

The bottom electrodes BE may be provided on the lower interlayer insulating layer 102 so as to be connected to the lower contact plugs 104, respectively. The magnetic tunnel junction patterns 124 may be provided on the bottom electrodes BE. The magnetic tunnel junction patterns 124 may be connected to the bottom electrodes BE, respectively. Top electrodes TE may be provided on the magnetic tunnel junction patterns 124 so as to be connected to the magnetic tunnel junction patterns 124, respectively.

The insulating layer 140r may be provided on a sidewall of each of the top electrodes TE. The insulating layer 140r may include at least one of oxygen or nitrogen and may include the same metal element as the top electrodes TE.

The upper interlayer insulating layer 150 may be provided on the lower interlayer insulating layer 102 and may cover, e.g., overlap, sidewalls of the bottom electrodes BE, the magnetic tunnel junction patterns 124, and the top electrodes TE. The insulating layer 140r may be positioned, e.g., directly, between sidewalls of each top electrode TE and a corresponding upper interlayer insulating layer 150.

Upper contact plugs 160 may be provided in the upper interlayer insulating layer 150 so as to be connected to the top electrodes TE, and the interconnection 170 may be provided on the upper interlayer insulating layer 150. The interconnection 170 may extend in one direction and may be electrically connected to the plurality of magnetic tunnel junction patterns 124 arranged along the one direction. Each of the magnetic tunnel junction patterns 124 may be electrically connected to the interconnection 170 through a corresponding one of the top electrodes TE and the upper contact plug 160 connected to the corresponding top electrode TE. The interconnection 170 may perform a function of a bit line.

According to embodiments, when the etch residues 128 are re-deposited on the sidewalls of the magnetic tunnel junction patterns 124, the etch residues 128 may be oxidized or nitrified using the first ion beams IB1 to form the insulating layer 140. Since the insulating layer 140 is removed using the second ion beams IB2, it is possible to easily, e.g., and completely, remove the etch residues 128 re-deposited on the sidewalls of the magnetic tunnel junction patterns 124 during etching. Here, the first ion beams IB1 may be generated from the first ion source IS1 including a relatively high concentration of the insulating source, and the second ion beams IB2 may be generated from the second ion source IS2 including a relatively low concentration of the insulating source. Accordingly, the insulating layer 140 may be easily formed, and the selective removal of the insulating layer 140 may be easily performed. In addition, the first ion beams IB1 may be irradiated toward the substrate 100 at a relatively high angle, so the insulating layer 140 may be formed to have a uniform thickness. The second ion beams IB2 may be irradiated to the substrate 100 at a relatively low angle, so the selective removal of the insulating layer 140 may be easily performed.

In other words, the etch residues 128 on the sidewalls of the magnetic tunnel junction patterns 124 may be easily removed to prevent an electrical short between the first magnetic pattern 112P and the second magnetic pattern 116P of each of the magnetic tunnel junction patterns 124. As a result, the magnetic memory device with excellent reliability may be manufactured.

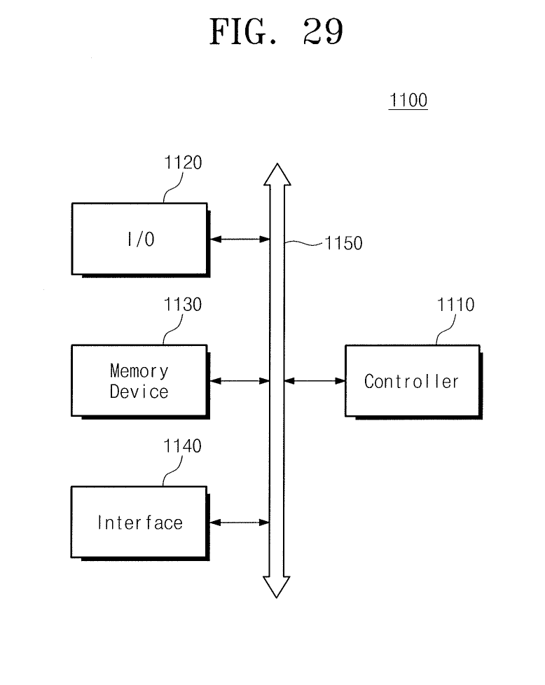

FIG. 29 is a schematic block diagram illustrating an electronic system including a semiconductor device according to an embodiment.

Referring to FIG. 29, an electronic system 1100 according to an embodiment may include a controller 1110, an input/output (I/O) unit 1120, a memory device 1130, an interface unit 1140, and a data bus 1150. At least two of the controller 1110, the I/O unit 1120, the memory device 1130, and the interface unit 1140 may communicate with each other through the data bus 1150. The data bus 1150 may correspond to a path through which electrical signals are transmitted.

The controller 1110 may include at least one of, e.g., a microprocessor, a digital signal processor, a microcontroller, or other logic devices having a similar function to any one thereof. The I/O unit 1120 may include, e.g., a keypad, a keyboard and/or a display device. The memory device 1130 may store data and/or commands. If the semiconductor devices according to the above mentioned embodiments are realized as semiconductor memory devices, the memory device 1130 may include at least one of the semiconductor memory devices according to the above mentioned embodiments. The interface unit 1140 may transmit electrical data to a communication network or may receive electrical data from a communication network. The interface unit 1140 may operate by wireless or cable. For example, the interface unit 1140 may include an antenna or a cable/wireless transceiver. Although not shown in the drawings, the electronic system 1100 may further include a fast dynamic random access memory (DRAM) device and/or a fast static random access memory (SRAM) device which acts as a working memory for improving an operation of the controller 1110.

The electronic system 1100 may be applied to, e.g., a personal digital assistant (PDA), a portable computer, a web tablet, a wireless phone, a mobile phone, a digital music player, a memory card, or other electronic products receiving and/or transmitting information data by wireless.

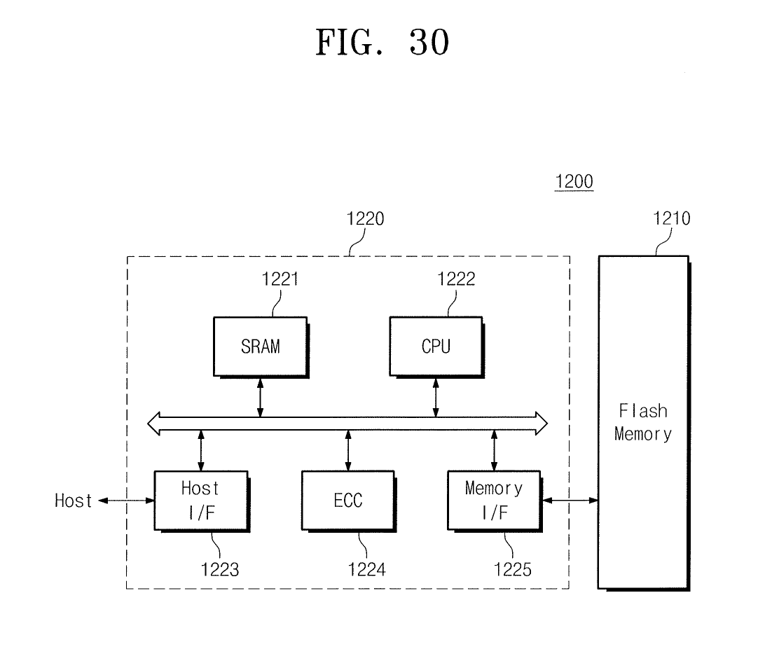

FIG. 30 is a schematic block diagram illustrating a memory card including a semiconductor device according to an embodiment.

Referring to FIG. 30, a memory card 1200 according to an embodiment may include a memory device 1210. If the semiconductor devices according to the aforementioned embodiments are realized as semiconductor memory devices, the memory device 1210 may include at least one of the semiconductor memory devices according to the aforementioned embodiments. The memory card 1200 may include a memory controller 1220 that controls data communication between a host and the memory device 1210.

The memory controller 1220 may include a central processing unit (CPU) 1222 that controls overall operations of the memory card 1200. In addition, the memory controller 1220 may include an SRAM device 1221 used as a working memory of the CPU 1222. Moreover, the memory controller 1220 may further include a host interface unit 1223 and a memory interface unit 1225. The host interface unit 1223 may be configured to include a data communication protocol between the memory card 1200 and the host. The memory interface unit 1225 may connect the memory controller 1220 to the memory device 1210. The memory controller 1220 may further include an error check and correction (ECC) block 1224. The ECC block 1224 may detect and correct errors of data which are read out from the memory device 1210. Even though not shown in the drawings, the memory card 1200 may further include a read only memory (ROM) device that stores code data for interfacing with the host. The memory card 1200 may be used as a portable data storage card. Alternatively, the memory card 1200 may be realized as a solid state disk (SSD) which is used as hard disks of computer systems.

By way of summation and review, according to embodiments, when etch residues are re-deposited on sidewalls of magnetic tunnel junction patterns during etching, the etch residues may be oxidized or nitrified using first ion beams to form an insulating layer. The insulating layer may be removed using second ion beams, so it is possible to easily remove the etch residues re-deposited on the sidewalls of the magnetic tunnel junction patterns via removal of the insulating layer, thereby improving the magnetic tunnel junction characteristics of the magnetic tunnel junction patterns. The first ion beams may be generated from a first ion source including a relatively high concentration of the insulating source, and the second ion beams may be generated from a second ion source including a relatively low concentration of the insulating source. Thus, the insulating layer may be easily formed, and the selective removal of the insulating layer may be easily performed. In addition, the first ion beams may be irradiated to the substrate at a relatively high angle, so the insulating layer may be formed to have a uniform thickness. Furthermore, the second ion beams may be irradiated to the substrate at a relatively low angle, so the selective removal of the insulating layer may be easier.

In other words, the etch residues re-deposited on the sidewalls of the magnetic tunnel junction patterns may be converted into an insulating material, which may be easily removed to prevent an electrical short between the first and second magnetic patterns of each of the magnetic tunnel junction patterns, while improving magnetic tunnel junction characteristics. As a result, the magnetic memory device with excellent reliability may be manufactured.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1. A method of forming patterns, the method comprising:
forming an etch target layer on a substrate;
patterning the etch target layer to form patterns;
forming an insulating layer on sidewalls of the patterns using a first ion beam generated from a first ion source; and
removing the insulating layer using a second ion beam generated from a second ion source,
wherein each of the first and second ion sources includes an insulating source, and
wherein the insulating source includes at least one of oxygen or nitrogen.

2. The method as claimed in claim 1, wherein a concentration of the insulating source in the first ion source is different from a concentration of the insulating source in the second ion source.

3. The method as claimed in claim 2, wherein the concentration of the insulating source in the first ion source is higher than the concentration of the insulating source in the second ion source.

4.-6. (canceled)

7. The method as claimed in claim 1, wherein:
forming the insulating layer includes irradiating the first ion beam at a first angle with respect to a top surface of the substrate, and
removing the insulating layer includes irradiating the second ion beam at a second angle with respect to the top surface of the substrate, the first angle being different from the second angle.

8. The method as claimed in claim 7, wherein the first angle is greater than the second angle.

9.-10. (canceled)

11. The method as claimed in claim 1, wherein forming the insulating layer includes forming a first insulating layer and a second insulating layer which are sequentially stacked on the sidewalls of the patterns,
wherein the first insulating layer is disposed between the second insulating layer and the sidewalls of the patterns,
wherein the insulating source of the first ion source is oxygen when the first insulating layer is formed, and
wherein the insulating source of the first ion source is oxygen and nitrogen when the second insulating layer is formed.

12. The method as claimed in claim 11, wherein a nitrogen concentration of the second insulating layer is higher than a nitrogen concentration of the first insulating layer.

13. The method as claimed in claim 1, wherein forming the insulating layer includes:
irradiating the first ion beam at a first angle with respect to a top surface of the substrate to form a first insulating layer;
irradiating the first ion beam at a second angle with respect to the top surface of the substrate to form a second insulating layer; and
irradiating the first ion beam at a third angle with respect to the top surface of the substrate to form a third insulating layer, the second angle being smaller than the first angle and the third angle.

14. (canceled)

15. The method as claimed in claim 13, wherein the first ion beam has a first incident energy when the first insulating layer is formed, and the first ion beam has a second incident energy greater than the first incident energy when the third insulating layer is formed.

16. The method as claimed in claim 13, wherein removing the insulating layer includes irradiating the second ion beam at a fourth angle with respect to the top surface of the substrate, the fourth angle being smaller than the first angle and the third angle.

17. (canceled)

18. The method as claimed in claim 1, wherein forming the insulating layer includes forming a first insulating layer and a second insulating layer which are sequentially stacked on the sidewalls of the patterns,
wherein the first insulating layer is disposed between the second insulating layer and the sidewalls of the patterns,
wherein the first ion beam has a first incident energy when the first insulating layer is formed, and
wherein the first ion beam has a second incident energy greater than the first incident energy when the second insulating layer is formed.

19. (canceled)

20. The method as claimed in claim 18, wherein:
the first ion beam is irradiated at a first angle with respect to a top surface of the substrate when the first insulating layer is formed,
the first ion beam is irradiated at a second angle with respect to the top surface of the substrate when the second insulating layer is formed, and
removing the insulating layer includes irradiating the second ion beam at a third angle with respect to the top surface of the substrate, the third angle being smaller than the first angle and the second angle.

21. (canceled)

22. A method of manufacturing a magnetic memory device, the method comprising:
forming a magnetic tunnel junction layer on a substrate;
patterning the magnetic tunnel junction layer to form magnetic tunnel junction patterns;
forming an insulating layer on sidewalls of the magnetic tunnel junction patterns using a first ion beam generated from a first ion source; and
removing the insulating layer using a second ion beam generated from a second ion source,
wherein each of the first and second ion sources includes an insulating source, and
wherein the insulating source includes at least one of oxygen or nitrogen.

23. The method as claimed in claim 22, wherein a concentration of the insulating source in the first ion source is higher than a concentration of the insulating source in the second ion source.

24. (canceled)

25. The method as claimed in claim 22, wherein:
forming the insulating layer includes irradiating the first ion beam at a first angle with respect to a top surface of the substrate, and
removing the insulating layer includes irradiating the second ion beam at a second angle with respect to the top surface of the substrate, the first angle being greater than the second angle.

26. The method as claimed in claim 22, further comprising forming top electrodes on the magnetic tunnel junction patterns before forming the insulating layer,
wherein each of the top electrodes is spaced apart from the substrate with each of the magnetic tunnel junction patterns interposed therebetween, and
wherein at least a portion of each of the top electrodes is oxidized or nitrified during the formation of the insulating layer.

27.-28. (canceled)

29. A method of forming patterns, the method comprising:
forming an etch target layer on a substrate;
patterning the etch target layer to form patterns;
irradiating a first ion beam from a first ion source toward the patterns, such that a first insulating source in the first ion source interacts with residue on the patterns to form an insulating layer on sidewalls of the patterns; and
removing the insulating layer from the sidewalls of the patterns,
wherein the first insulating source includes at least one of oxygen or nitrogen.

30. The method as claimed in claim 29, wherein removing the insulating layer from the sidewalls of the patterns is performed using a second ion beam generated from a second ion source, the second ion source including a second insulating source, and the second insulating source including at least one of oxygen or nitrogen.

31. (canceled)

32. The method as claimed in claim 29, wherein irradiating the first ion beam from the first ion source includes interacting the first insulating source in the first ion beam with metal elements in the residue on sidewalls of the patterns to form the insulating layer, the residue including metal elements of the tech target layer redeposited on the sidewalls of the patterns after patterning the etch target layer.

33. The method as claimed in claim 32, wherein removing the insulating layer from the sidewalls of the patterns includes removing the residue from the sidewalls of the patterns.

34.-35. (canceled)
